(19) United States
(12) Patent Application Publication
(10) Pub. No.: US 2025/0298400 A1
(43) Pub. Date: Sep. 25, 2025

(54) SUBSTRATE PROCESSING APPARATUS

(71) Applicant: Tokyo Electron Limited, Tokyo (JP)

(72) Inventors: Toyohisa TSURUDA, Kumamoto (JP); Naoto NAKAMURA, Kumamoto (JP)

(21) Appl. No.: 19/081,103

(22) Filed: Mar. 17, 2025

(30) Foreign Application Priority Data
Mar. 25, 2024 (JP) 2024-047990
Jan. 16, 2025 (JP) 2025-006267

(51) Int. Cl. G05B 19/418; H01L 21/67

(52) U.S. Cl. CPC G05B 19/41835; H01L 21/67023; H01L 21/67167; G05B 2219/45031

(57) ABSTRACT

A substrate processing apparatus includes: a plurality of processing devices each configured to execute a process on a substrate; a recipe storage storing a reference recipe indicating conditions for the process; an offset storage storing, in association with the reference recipe, an offset table including a plurality of offset values respectively corresponding to a plurality of processing devices; and circuitry configured to: select one device from the plurality of processing devices; extract an offset value corresponding to the selected device from the plurality of offset values; and generate a process recipe, based on the reference recipe and the extracted offset value; and cause the selected device to execute the process on the substrate according to the generated process recipe.

### CROSS-REFERENCE TO RELATED APPLICATIONS

This application is based upon and claims the benefit of priority from Japanese Patent Application No. 2025-006267, filed on Jan. 16, 2025, and Japanese Patent Application No. 2024-047990, filed on Mar. 25, 2024, the entire contents of which are incorporated herein by reference.

### BACKGROUND

### Field

The present disclosure relates to a recipe setting apparatus.

### Description of the Related Art

Japanese Unexamined Patent Application Publication No. 2023-072178 discloses a coating and developing apparatus. Japanese Unexamined Patent Publication No. 2023-072178 includes a plurality of modules for processing, and each module includes a liquid processing unit and a heat processing unit. For example, the liquid processing unit rotates a wafer (substrate) in a state in which a processing liquid is supplied, thereby forming a film of the processing liquid on the wafer.

A controller controlling the above coating and developing apparatus has a function for adjusting film thickness among modules. Here, the term “module” refers to a unit that performs a process on the wafer, such as the above-mentioned liquid processing unit or heat processing unit. In the coating and developing apparatus of Japanese Unexamined Patent Publication No. 2023-072178, to reduce a difference in the film thickness distribution resulting from processes performed by different modules, the recipe employed for each module during processing is adjusted.

### SUMMARY

Disclosed herein is a substrate processing apparatus. The substrate processing apparatus may include: a plurality of processing devices each configured to execute a process on a substrate; a recipe storage storing a reference recipe indicating conditions for the process; an offset storage storing, in association with the reference recipe, an offset table including a plurality of offset values respectively corresponding to a plurality of processing devices; and circuitry configured to: select one device from the plurality of processing devices; extract an offset value corresponding to the selected device from the plurality of offset values; and generate a process recipe, based on the reference recipe and the extracted offset value; and cause the selected device to execute the process on the substrate according to the generated process recipe.

Additionally, an apparatus is disclosed herein. The apparatus may include: a recipe storage storing a reference recipe indicating conditions for the process on a substrate; an offset storage storing, in association with the reference recipe, an offset table including a plurality of offset values respectively corresponding to a plurality of processing devices; and circuitry configured to: select one device from the plurality of processing devices; extract an offset value corresponding to the selected device from the plurality of offset values; and generate a process recipe, to cause the selected device to execute the process on the substrate according to the process recipe, based on the reference recipe and the extracted offset value.

Additionally, a method is disclosed herein. The method may include: storing a reference recipe indicating conditions for substrate processing; storing, in association with the reference recipe, an offset table that includes a plurality of offset values respectively corresponding to a plurality of modules of a substrate processing apparatus; selecting one module from the plurality of modules; extracting, from the plurality of offset values, an offset value corresponding to the selected module; generating a process recipe, to be executed by the selected module, based on the reference recipe and the extracted offset value; and causing the selected device to execute the process on the substrate according to the generated process recipe.

### BRIEF DESCRIPTION OF THE DRAWINGS

FIG. 1 is a plan view schematically illustrating an example overview of the configuration of a wafer processing system.

FIG. 2 is a front view schematically illustrating an example overview of the configuration of the wafer processing system.

FIG. 3 is a diagram showing an example of a block diagram of a controller.

FIG. 4 is a diagram showing one example of a module configuration in a processing station.

FIG. 5 is a diagram showing an example of a module serving as a liquid processing unit.

FIG. 6 is a diagram showing an example of a measurement unit.

FIG. 7 is a diagram showing an example of a correspondence relationship of recipes.

FIG. 8A is a diagram schematically showing a film thickness distribution of a processed film.

FIG. 8B is a diagram for explaining reducing the average film thickness and film thickness distribution difference.

FIG. 8C is a diagram for explaining bringing the average film thickness distribution closer to a target value while keeping the average film thickness constant.

FIG. 9 is another example of the block diagram of the controller.

FIG. 10 is a diagram showing an example of a hardware configuration of the controller.

FIG. 11 is a diagram showing a series of processing flows in which the difference in film thickness distribution among a plurality of modules is reduced, and the average film thickness in each module is controlled to be a target value.

FIG. 12 is a diagram showing a series of processing flows of offset value changes by a manual changing unit.

FIG. 13 is a diagram showing one example of an offset table list.

FIG. 14 is a diagram showing one example of an input interface.

FIG. 15 is a diagram showing one example of a change history.

FIG. 16 is a diagram showing one example of a second input interface.

FIG. 17 is a diagram showing a series of processing flows in which a substrate processing control unit performs liquid processing by generating a process recipe.

FIG. 18 is another example of the block diagram of the controller.

FIG. 19 is a diagram showing one example of a monitoring interface.

FIG. 20 is a diagram showing another example of the monitoring interface.

FIG. 21 is a diagram showing another example of the offset table list.

FIG. 22 is a diagram showing a series of processing flows for monitoring a plurality of offset values.

### DETAILED DESCRIPTION

In the following description, with reference to the drawings, the same reference numbers are assigned to the same components or to similar components having the same function, and overlapping description is omitted.

### [Wafer Processing System]

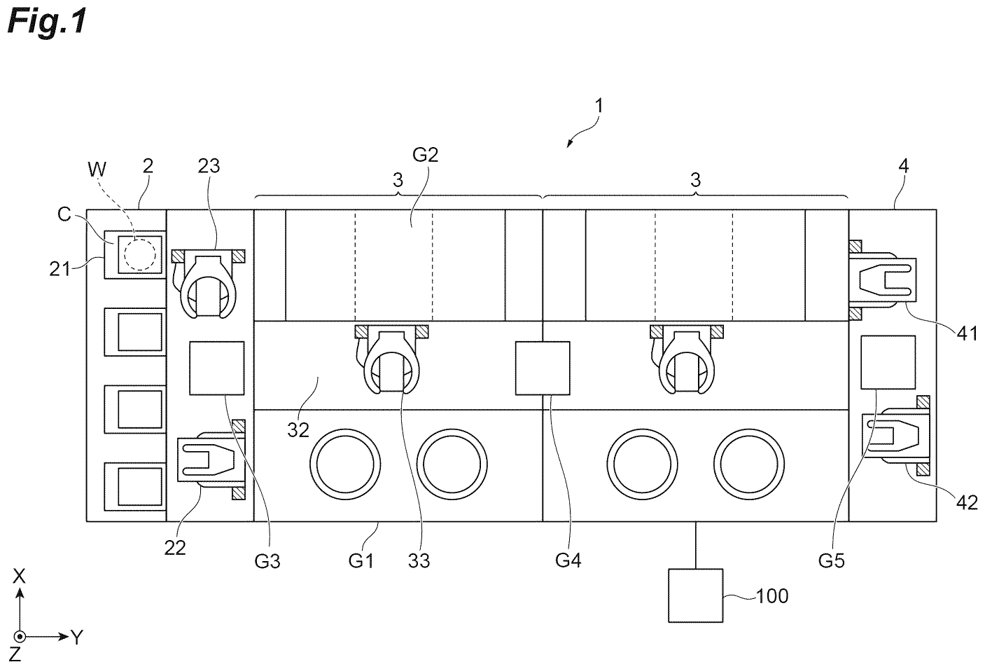

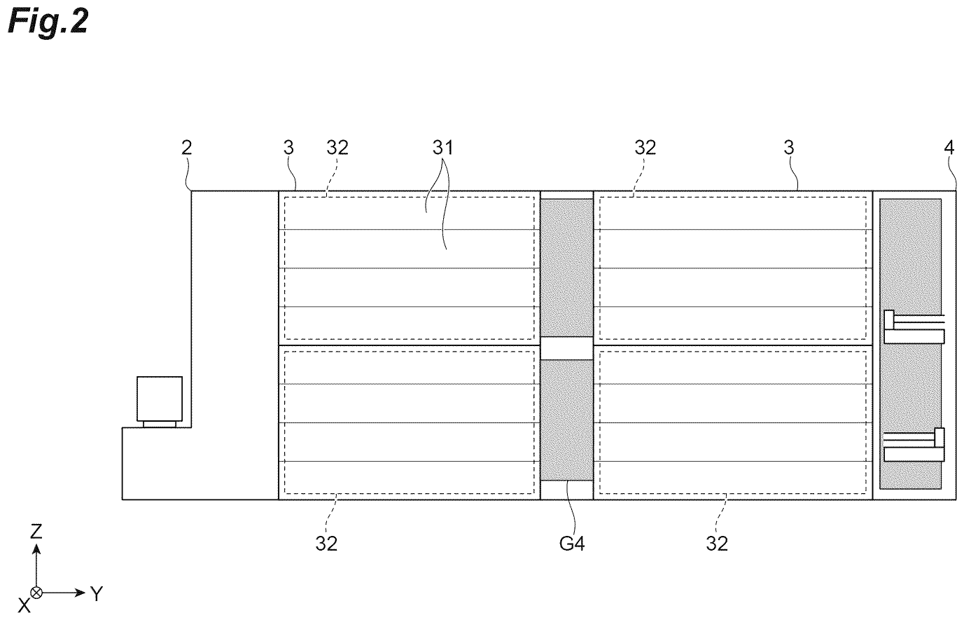

First, an example configuration of a wafer processing system is explained. FIGS. 1 and 2 are respectively a plan view and a front view schematically illustrating example overviews of a configuration of a wafer processing system 1. The wafer processing system 1 is described as an example that performs a photolithography process for forming and developing a resist film on a wafer (substrate) W.

As shown in FIG. 1, the wafer processing system 1 has a cassette station 2 into and out of which cassettes C accommodating a plurality of wafers W are carried, and a processing station 3 provided with a plurality of various processing apparatuses for applying predetermined processes to the wafers W. The processing station 3 is an example of a substrate processing apparatus. Further, the wafer processing system 1 has a configuration in which the cassette station 2, the processing station 3, and an interface station 4 are integrally connected, wherein the interface section 4 is configured to deliver and receive wafers W to and from an exposure apparatus (not shown). Note that, as shown in FIG. 1, two processing stations 3 are provided between the cassette station 2 and the interface station 4, but one processing station 3 or three or more processing sections 3 may be provided instead.

The cassette station 2 is provided with a plurality of cassette mounting tables 21 and wafer transfer devices 22 and 23. The cassette station 2 uses the wafer transfer devices 22 or 23 to transfer wafers W between a cassette C mounted on a mounting table 21 and the processing station 3. For example, each of the wafer transfer devices 22 and 23 is provided with drive mechanisms for at least one of X-direction, Y-direction, vertical direction, and around a vertical axis (θ-direction), and may also be provided with drive mechanisms for all of the directions.

At least one of the wafer transfer devices 22 and 23 is configured to transfer wafers W to and from the cassette C, and is also configured to transfer wafers W to and from the processing station 3. Transferring wafers W to and from the processing station 3 includes, for example, transferring wafers W to and from a third block G3 provided with a transfer device accessible by a wafer transfer device 33 inside the processing station 3. The third block G3 may have a plurality of transfer devices (not shown) aligned in the vertical direction.

Optionally, the cassette station 2 may also be provided with an inspection apparatus (not shown) for inspecting wafers W, at a position accessible by at least one of the wafer transfer devices 22 and 23.

The processing station 3 is an example of a substrate processing apparatus. The processing station 3 is provided with multiple blocks, for example, three blocks: a first block G1, a second block G2, and a fourth block G4. Also, as shown in FIG. 2, multiple layers 31 each including the first block G1 and the second block G2 are stacked in the vertical direction. For example, on the front side of the processing station 3 (the negative X-direction side in FIG. 1), the first block G1 is provided; on the rear side of the processing station 3 (the positive X-direction side in FIG. 1), the second block G2 is provided. At the connection portion between the processing station 3 and the interface station 4 (the positive Y-direction side of the processing station 3 in FIG. 1) or between adjacent processing stations 3, the fourth block G4 is provided. The fourth block G4 may have a plurality of transfer devices aligned in the vertical direction. Also, the foregoing third block G3 may be provided in the processing station 3.

The first block G1 has a plurality of processing apparatuses, e.g., both a patterning film forming apparatus (not shown) and a developing apparatus (not shown). The patterning film forming apparatus may include, for example, in addition to a resist film forming apparatus, an anti-reflection film forming apparatus. For example, a plurality of processing apparatuses are arranged in a horizontal row. The number, arrangement, and types of these processing apparatuses can be selected arbitrarily.

In these patterning film forming apparatuses and developing apparatuses, a predetermined processing liquid is supplied to the wafer W, or a predetermined processing gas is supplied to the wafer W, for example. In that way, in the patterning film forming apparatus, a resist film to be utilized as a mask when forming a pattern in a lower-layer film, and an anti-reflection film for facilitating an exposure process such as optical irradiation, or the like are formed efficiently. In the developing apparatus, partial removal of the exposed resist film occurs, forming an uneven shape as the mask.

For instance, in the second block G2, a heat processing apparatus (not shown), configured to perform heat processing such as heating or cooling the wafer W, is arranged in a vertical and horizontal arrangement. Although not shown, the second block G2 may also be provided with, in vertical-and-horizontal arrangements (Z-direction in FIG. 2), a hydrophobic processing apparatus for performing hydrophobic processing to enhance the adhesion between a resist liquid and the wafer W, and a peripheral exposure apparatus for exposing the outer periphery of the wafer W. The numbers and arrangement of these heat processing apparatuses, the hydrophobic processing apparatus, and the peripheral exposure apparatus are also selectable arbitrarily.

As shown in FIG. 1, in a plan view, a wafer transfer region 32 is formed in a region sandwiched between the first block G1 and the second block G2. A wafer transfer device 33 is disposed in the wafer transfer region 32, for example.

The wafer transfer device 33 has a transfer arm that is movable, for example, in the X-direction, Y-direction, the θ-direction, and the vertical direction. The wafer transfer device 33 moves within the wafer transfer region 32 and can transfer wafers W to a predetermined apparatus in the surrounding first block G1, the second block G2, the third block G3, or the fourth block G4. In the case shown in FIG. 1, when there are a plurality of processing stations 3, the wafer transfer device 33 in the processing station 3 located on the interface station 4 side can transfer wafers W to a predetermined apparatus in the first block G1, the second block G2, the fourth block G4, and a fifth block G5 described later.

A plurality of wafer transfer devices 33 may be disposed in the vertical direction. One wafer transfer device 33 can transfer wafers W to predetermined apparatuses located at the height of the upper layers 31 in the multiple layers 31 stacked in the vertical direction (see FIG. 2). Another wafer transfer device 33 can transfer wafers W to predetermined apparatuses located at the height of multiple layers 31 below. A plurality of wafer transfer regions 32 are provided to enable such transfer of wafer W. The number of wafer transfer devices 33 and the number of layers 31 that one wafer transfer device 33 is responsible for can be selected arbitrarily, such as providing one wafer transfer device 33 per layer 31.

Further, a shuttle transfer device (not shown) may be provided in the wafer transfer region 32, or in the first block G1 or the second block G2. The shuttle transfer device transfers wafers W linearly between one space adjacent to one side of the processing station 3 and another space adjacent to a side of the processing station 3 opposite to the one side.

The interface station 4 is provided with a fifth block G5 having a plurality of transfer devices and wafer transfer devices 41 and 42. The interface station 4 uses the wafer transfer devices 41 or 42 to transfer wafers W between a transfer device inside the fifth block G5, to and from which the wafer transfer device 33 delivers and receives wafers W, and the exposure apparatus. For example, each of the wafer transfer devices 41 and 42 is provided with drive mechanisms for at least one of the X-direction, Y-direction, vertical direction, and around a vertical axis (θ-direction), and may also have drive mechanisms for all of the directions. At least one of the wafer transfer devices 41 and 42 supports a wafer W and transfers it between the transfer device inside the fifth block G5 and the exposure apparatus.

A cleaning apparatus for cleaning the surface of the wafer W, or an above described peripheral exposure apparatus may be provided at a position of the interface station 4 accessible for at least one of the wafer transfer devices 41 and 42.

Although the inspection apparatus may be provided in the cassette station 2 as described, it may also be provided in either the processing station 3 or the interface station 4 at a location accessible by a transfer arms (33, 41, 42 in FIG. 1 or FIG. 2) provided therein.

The wafer processing system 1 described above is provided with a controller 100. The controller 100 is, for example, a computer having a program storage unit (not shown). The program storage unit stores a program for controlling the processing of wafers W in the wafer processing system 1. The program storage unit also stores a program for controlling an operation of each drive system of various processing apparatuses and transfer devices so as to realize wafer processing in the wafer processing system 1. Note that the above program may have been installed in the controller 100 from a computer-readable storage medium in which that program was recorded.

### [Operation of Wafer Processing System]

The wafer processing system 1 is configured as described above. Next, an example of wafer processing performed using the wafer processing system 1 having the above configuration will be described.

First, a cassette C accommodating a plurality of wafers W is carried into the cassette station 2 of the wafer processing system 1 and placed on a cassette mounting table 21. Next, each wafer W in the cassette C is sequentially taken out by the wafer transfer device 22 or 23, and transferred to the transfer device in the third block G3.

The wafer W transferred to the transfer device in the third block G3 is supported by the wafer transfer device 33 and transferred to a hydrophobic processing apparatus in the second block G2, where hydrophobic processing is performed. Then, by the wafer transfer device 33, the wafer W is transferred to a resist film forming apparatus, which forms a resist film on the wafer W, and subsequently, the wafer W is transferred to a heat processing apparatus to undergo a pre-baking process, and then transferred to the transfer device in the fifth block G5. When there are a plurality of processing stations 3 as in FIGS. 1 and 2, the wafer W may be placed in the transfer device in the fourth block G4 once, and then transferred to and from a plurality of wafer transfer devices 33, prior to being transferred to the transfer device in the fifth block G5. The wafer W may also be transferred by the wafer transfer device 33 to a peripheral exposure apparatus, where the outer periphery of the wafer W undergoes exposure processing.

The wafer W transferred to the transfer device in the fifth block G5 is transferred by the wafer transfer devices 41 and 42 to an exposure apparatus, where it undergoes an exposure process in a given pattern. Note that cleaning of the wafer W by a cleaning apparatus may be performed before the exposure process.

The wafer W having undergone the exposure process is transferred back to the transfer device in the fifth block G5 by the wafer transfer devices 41 and 42. Then, the wafer W is transferred by the wafer transfer device 33 to the heat processing apparatus where a post-exposure bake is performed.

The wafer W that has undergone the post-exposure bake is transferred by the wafer transfer device 33 to a developing apparatus, where the wafer W is developed. After the completion of development, the wafer W is transferred by the wafer transfer device 33 to a heat processing apparatus 40 for post-baking.

Subsequently, the wafer W is transferred by the wafer transfer device 33 to the transfer device in the third block G3, and transferred back into the cassette C on the cassette mounting table 21 by the wafer transfer device 22 or 23 in the cassette station 2. Thus, a series of photolithography processes is completed.

The wafer processing system in this disclosure is not limited to the above configuration and operation. For example, the wafer W is exchanged between the interface station 4 and the exposure apparatus, but the exposure apparatus may not be directly connected. In that case, for example, after wafer W is transferred from the cassette station 2 to the processing station 3 and subjected to a processing, it is transferred back to the cassette station 2 to be carried out externally. Also, any of the above-mentioned processing apparatuses may not be included, or the process in any of the above-mentioned processing apparatuses may be omitted.

The configuration of the substrate processing apparatus is not limited to the processing station 3. The substrate processing apparatus may have any configuration as long as it includes a processing apparatus that performs photolithography on wafer W and a control unit 10 capable of controlling it.

### [Overview of Recipe Setting Apparatus]

As described above, the processing station 3 has a plurality of modules. For example, the processing station 3 includes, as a plurality of modules, a plurality of liquid processing modules (for example, the “resist film forming apparatus” described above) performing liquid processing in the first block G1. As another example of the plurality of modules, the processing station 3 may include a plurality of heat processing modules (for example, the “heat processing apparatus” described above) performing heat processing in the second block G2. Substrate processing in each module is performed based on a predetermined process recipe. However, increasing the number of modules increases the number of process recipes to be managed. Each module's process recipe includes many items to be adjusted. If one attempts to edit each process recipe individually, it becomes very burdensome for the user and can also cause mistakes such as selecting an item other than the actual adjustment target item.

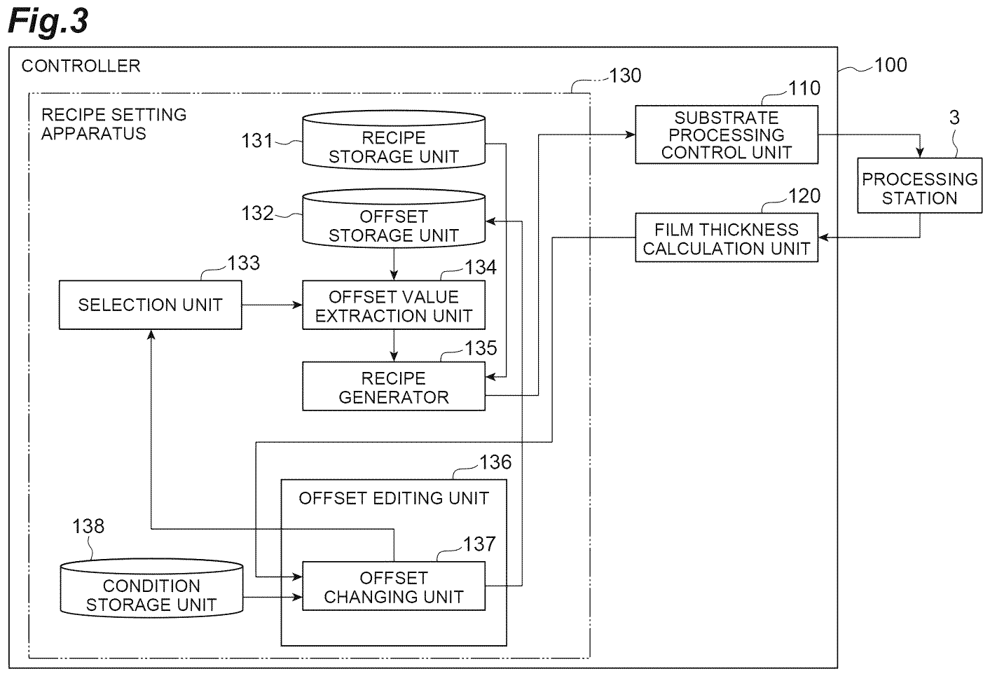

Accordingly, as shown in FIG. 3, the controller 100 includes a recipe setting apparatus 130. The recipe setting apparatus 130 is configured to set and change a process recipe executed in each module. The recipe setting apparatus 130 stores a reference recipe indicating conditions for substrate processing. Further, the recipe setting apparatus 130 stores, in association with that reference recipe, an offset table that includes a plurality of offset values respectively corresponding to a plurality of modules. The recipe setting apparatus 130 is configured to extract from among the plurality of offset values, the offset value corresponding to a selected module, and based on the reference recipe and the extracted offset value, generates a process recipe for the selected module. According to the recipe setting apparatus 130, for each item in the reference recipe to be adjusted on a module-by-module basis, a plurality of offset values corresponding to the plurality of modules respectively is gathered in the offset table. The extraction of the offset value, and the generation of a process recipe based on the reference recipe and the extracted offset value, are carried out for each module. Thus, by doing a simple set of operations in which the offset table is edited collectively, rather than opening each recipe and searching for items, the process recipe for each module may readily be managed.

The above configuration can be applied to various stages of substrate processing. As one example, an application to a film forming (e.g., resist film formation) by a plurality of liquid processing modules will be described. The above configuration can be applied to various stages of substrate processing. As one example, an application to a film forming (e.g., resist film formation) by a plurality of liquid processing modules will be described.

### [Module Configuration]

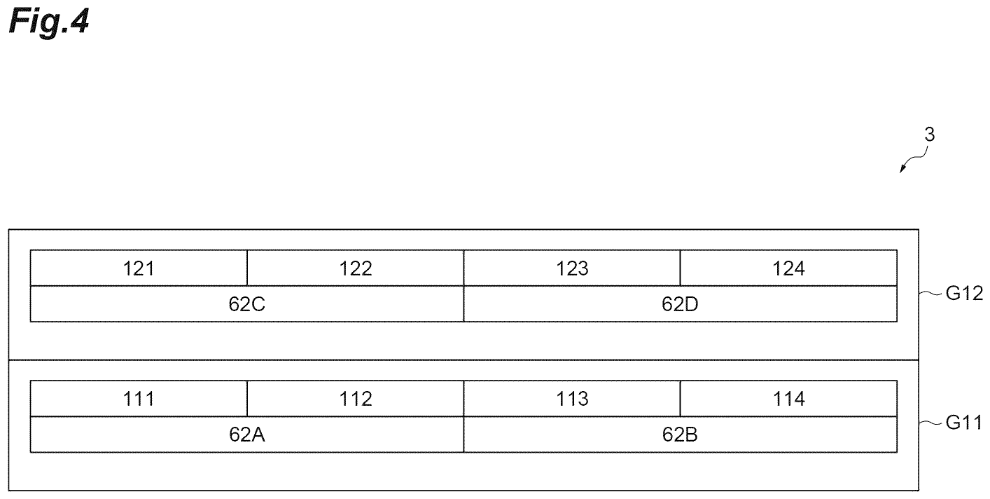

FIG. 4 shows an example of the arrangement of a plurality of liquid processing modules in the processing station 3. In the example of FIG. 4, the processing station 3 has two first blocks G11, G12 that are partitioned from each other. The first block G11 includes four modules 111 to 114. The second block G12 includes four modules 121 to 124.

In the following description, the plurality of modules is described as being constituted by modules 111 to 124.

Each of the plurality of modules 111 to 124 may be connected to one or more sources of a processing medium. The processing medium is a medium that temporarily provided on the wafer W to facilitate processing. The processing medium may be a processing liquid, for example, or may be a processing gas. In the example of FIG. 4, each of the plurality of modules 111 to 124 is connected to one of four sources (a plurality of sources). For instance, modules 111 and 112 are connected to a common source 62A, which supplies a processing liquid to modules 111 and 112. Modules 113 and 114 are connected to a common source 62B, which supplies a processing liquid to modules 113 and 114. Modules 121 and 122 are connected to a common source 62C, which supplies a processing liquid to modules 121 and 122. Modules 123 and 124 are connected to a common source 62D, which supplies a processing liquid to modules 123 and 124.

### [Liquid Processing Module]

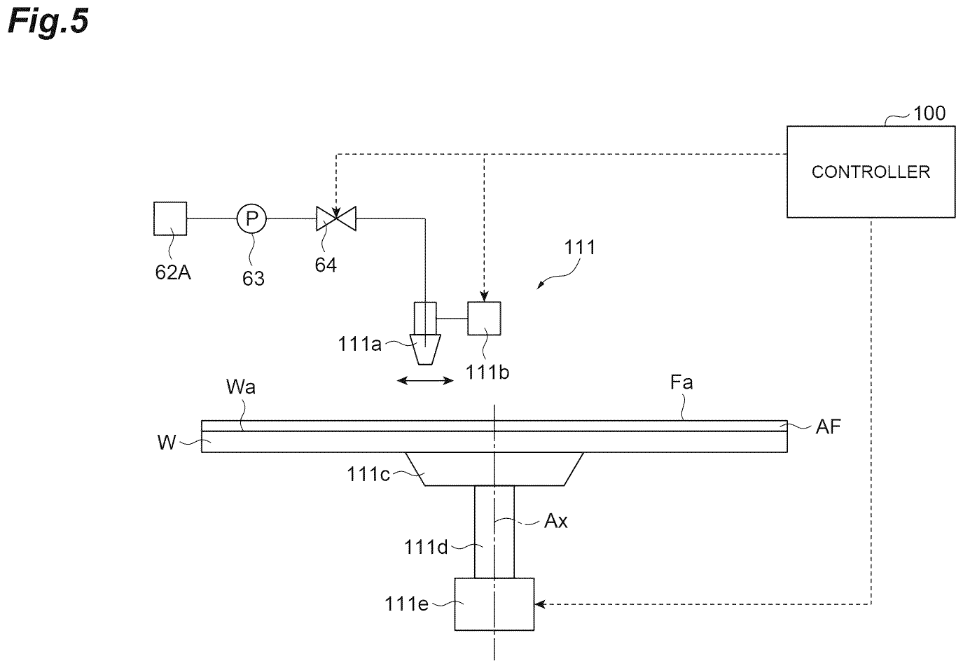

Next, an example of the configuration of a liquid processing module is described. Because the configurations of modules 111 to 124 are common, module 111 is illustrated as a representative example. FIG. 5 is a diagram showing one example of the configuration of module 111. FIG. 5 shows a state in which a processed film AF is formed on wafer W.

As shown in FIG. 5, module 111 includes a nozzle 111a, a nozzle driving unit 111b, a holding unit 111c, a shaft 111d, and a rotation driving unit 111e. The nozzle 111a is connected via an on-off valve 64 to a pump 63 and the source 62A. The pump 63 and the on-off valve 64 may be common to multiple modules as well, like the source 62A. For example, modules 111 and 112 may be connected to the common pump 63 and the on-off valve 64.

The holding unit 111c (support) is configured to support the wafer W. For example, the holding unit 111c supports the central portion of the wafer W, which is placed horizontally with its surface Wa facing upward, and holds it by vacuum suction or the like. The upper surface of the holding unit 111c (the surface that supports the wafer W) may be formed in a circular shape as viewed from above, and may have a radius of about ⅙ to ½ the radius of the wafer W. A rotation driving unit 111e is connected underneath the holding unit 111c via the shaft 111d.

The rotation driving unit 111e is an actuator that includes, for example, a motor or another power source, and configured to rotate the holding unit 111c around a vertical axis Ax. In accordance with a rotation of the holding unit 111c by the rotation driving unit 111e, the wafer W held (supported) by the holding unit 111c rotates. The holding unit 111c may hold the wafer W so that the center of wafer W is substantially aligned with the axis Ax.

The nozzle 111a is configured to discharge a processing liquid onto the surface Wa of the wafer W that is held by the holding unit 111c. For example, the nozzle 111a is disposed above the wafer W (vertically above the wafer W's center) and discharges the processing liquid downward. The processing liquid may be, for instance, a solution (resist) for forming a resist film. The source 62A supplies the processing liquid to the nozzle 111a. Note that a pump 63 for adjusting the supply volume of the processing liquid may be provided between the source 62A and the nozzle 111a. The pump 63 is configured to pressurize the processing liquid in a channel of the processing liquid so that the processing liquid can be discharged from the nozzle 111a.

The on-off valve 64 is disposed on a supply path between the nozzle 111a and the source 62A. The on-off valve 64 is configured to switch the supply path between open and closed states. The nozzle driving unit 111b is configured to move the nozzle 111a between a discharge position above wafer W and a retracted position away from that discharge position. The discharge position is, for example, located vertically above the rotation center of wafer W (on the axis Ax). The retracted position (standby position) is, for example, set at a location outside the wafer W's periphery.

### [Measurement Module]

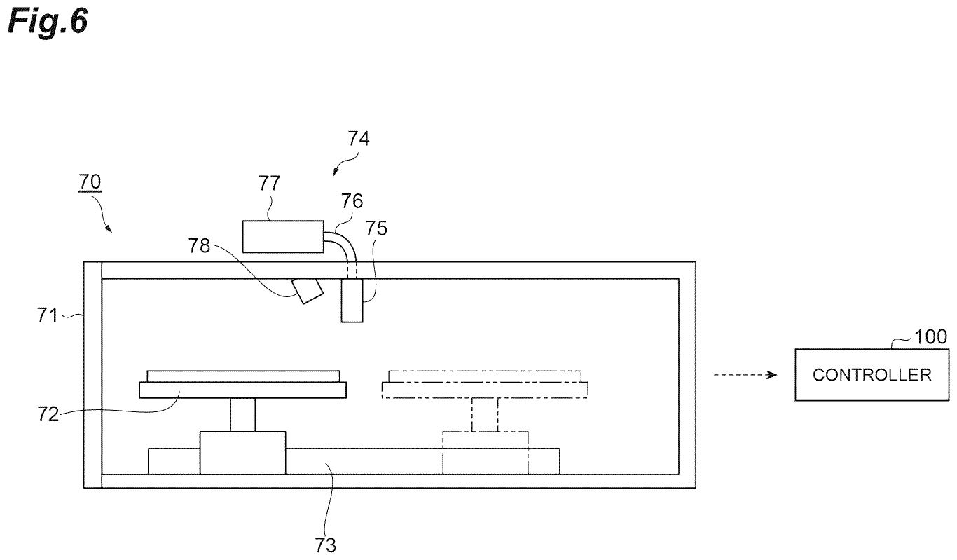

The processing station 3 may further include a measurement unit for obtaining information about the film thickness of the film formed by each of the modules 111 to 124. This measurement unit may be provided for each of the modules 111 to 124, or one measurement unit may be shared among the plurality of modules 111 to 124. FIG. 6 is a diagram showing an example of a measurement unit.

As shown in FIG. 6, the measurement unit 70 functions as a measurement unit for film thickness measurement. For example, the measurement unit 70 includes a housing 71, a measurement holding unit 72, a linear driving unit 73, and a spectroscopic measurement unit 74. The measurement holding unit 72 may be configured so that a portion for placing the wafer W can rotate relative to the housing 71. In that case, a rotation axis may be the center of the wafer W held by the measurement holding unit 72. By rotating above the measurement holding unit 72, the wafer W can also be rotated. Further, the linear driving unit 73 uses, for example, an electric motor or the like as a power source, and is configured to move the measurement holding unit 72 along a horizontal linear path.

The spectroscopic measurement unit 74 has a function of receiving light from the wafer W, splitting that light, and obtaining a spectral distribution. The spectroscopic measurement unit 74 includes an entrance portion 75 that receives light from the wafer W, a waveguide portion 76 that guides light entering the entrance portion 75, a spectroscope 77 that splits the light guided through the waveguide portion 76 to obtain its spectral distribution, and a light source 78. The entrance portion 75 is configured to receive light from the center portion of wafer W, while the wafer W held by the measurement holding unit 72 is driven by the linear driving unit 73 to move. For example, the entrance portion 75 is provided on a moving path of the measurement holding unit 72 that is driven by the linear driving unit 73 to move. Accordingly, the entrance portion 75 is provided so that the entrance portion 75 moves relative to the wafer W's surface in the wafer W's radial direction, in response to the wafer W moving together with a movement of the measurement holding unit 72. Thus, the spectroscopic measurement unit 74 can obtain a spectral distribution at each position along the radial direction of the wafer W, including the center thereof. The waveguide portion 76 is configured, for example, by an optical fiber or the like. The spectroscope 77 is configured to split the received light to obtain a spectral distribution including intensity information in each wavelength. The light source 78 irradiates illumination light downward, which is reflected by the wafer W and then enters the spectroscope 77 through the entrance portion 75 and the waveguide portion 76.

The spectral distribution data obtained by the spectroscope 77 is sent to the controller 100. Based on the spectral distribution data, the controller 100 can estimate the thickness of the film on the surface of wafer W, and the estimated result is stored in the controller 100 as the inspection result. An example method of estimating the film thickness of the wafer W's surface from the spectral distribution data is, for example, creating a model in advance that relates the wafer W surface's film thickness and the spectral distribution data. In such a case, by applying the model to the spectral distribution data obtained from the wafer W to be measured, the film thickness can be estimated. However, the method of estimating the film thickness of the film on the surface of the wafer W is not limited to the above.

### [Controller]

The above-described controller 100 is configured to control each of the plurality of modules 111 to 124 so that a film is formed on the surface of wafer W by supplying the processing liquid. The controller 100 may also be configured to control the measurement unit to acquire information on the film thickness of the film formed by modules 111 to 124.

The controller 100 constitutes at least part of the recipe setting apparatus 130. For example, the controller 100 is configured to: store a reference recipe; store, in association with the reference recipe, an offset table that includes a plurality of offset values respectively corresponding to the plurality of modules 111 to 124; select one module from among the plurality of modules 111 to 124; extract from among the plurality of offset values, the offset value corresponding to the selected module; and generate, based on the reference recipe and the extracted offset value, a process recipe to be executed by the selected module.

Referring again to FIG. 3, FIG. 3 is a block diagram showing a functional configuration of the controller 100. As illustrated in FIG. 3, the controller 100 includes, as functional components (hereinafter referred to as “functional modules”), a substrate processing control unit 110 and a film thickness calculation unit 120. Further, the controller 100 includes, as constituent elements of the recipe setting apparatus 130, a recipe storage unit 131, an offset storage unit 132, a selection unit 133, an offset value extraction unit 134, and a recipe generator 135. Processing executed by these functional modules corresponds to processing executed by the recipe setting apparatus 130, and also corresponds to processing executed by the controller 100.

The substrate processing control unit 110 is configured to control each of the plurality of modules 111 to 124 so that a predetermined film is formed on the surface of wafer W by supplying the processing liquid. For example, the substrate processing control unit 110 is configured to cause each of the modules 111 to 124 to perform liquid processing on the wafer W by supplying the processing liquid according to the process recipe generated by the recipe setting apparatus 130 so that the predetermined film is formed on the wafer W.

The film thickness calculation unit 120 has a function of estimating the film thickness of the processed film based on measurement results from the measurement unit. For example, the film thickness calculation unit 120 holds, beforehand, a film thickness model that associates a spectral distribution with film thickness. Based on the spectral distribution data obtained by the spectroscopic measurement unit 80 and the film thickness model, the film thickness calculation unit 120 estimates the film thickness. The method of film thickness calculation by the film thickness calculation unit 120 may be changed depending on the configuration of the measurement unit.

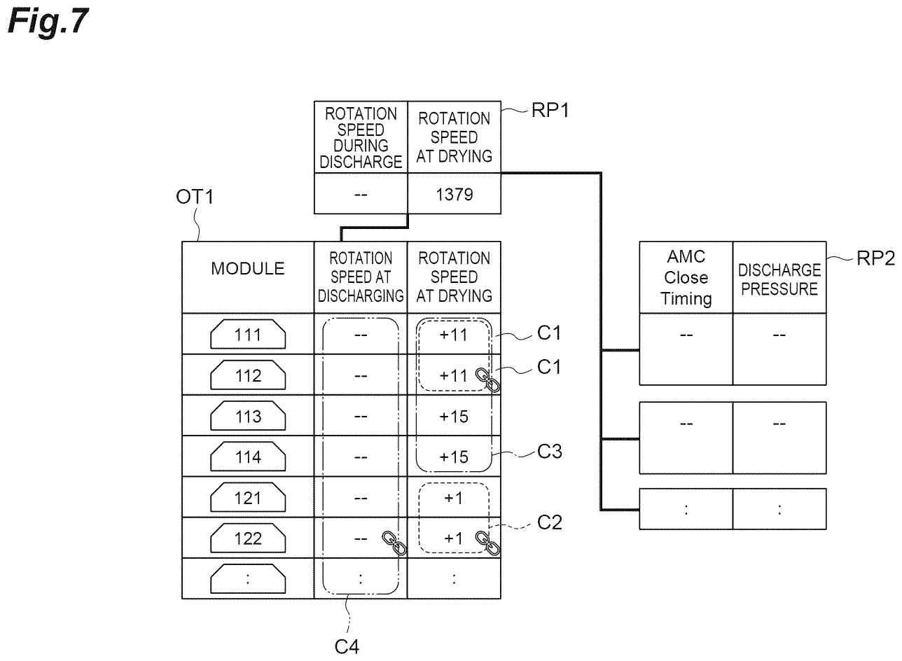

The recipe storage unit 131 stores a reference recipe indicating conditions for substrate processing. The reference recipe includes parameter settings of one or more control parameters related to substrate processing. The recipe storage unit 131 stores the reference recipe in association with modules. For instance, the recipe storage unit 131 stores, in association with modules 111 to 124, a reference recipe RP1 (see FIG. 7) for causing the modules 111 to 124 to form the predetermined film. As one example, the reference recipe RP1 includes a “rotation speed at discharging” and a “rotation speed at drying.” The rotation speed at discharging (a first setting value) is a control parameter that indicates the rotational speed (for example, number of rotations per minute) of wafer W while the processing liquid is discharged onto wafer W. The rotation speed at drying (a second setting value) is a control parameter that indicates the rotational speed of wafer W while drying the liquid film formed on wafer W by supplying the processing liquid. The rotation speed at discharging and the rotation speed at drying influence the average film thickness and the film thickness distribution in the plane of wafer W.

The offset storage unit 132 stores the offset table in association with the reference recipe. The offset table includes offset values respectively corresponding to the plurality of modules. An offset value represents, for example, an offset amount (e.g., a difference) with respect to the parameter setting value of a control parameter in the reference recipe RP1.

For example, as shown in FIG. 7, the offset storage unit 132 stores, in association with the reference recipe RP1, an offset table OT1. The offset table OT1 includes a plurality of offset values respectively corresponding to the plurality of modules 111 to 124. For instance, the offset table OT1 associates identification information of the plurality of modules 111 to 124 with the plurality of offset values. The offset table OT1, for each of the plurality of modules 111 to 124, includes an offset value for the rotation speed at discharging and an offset value for the rotation speed at drying. For example, in FIG. 7, with respect to the parameter setting value of 1379 for the rotation speed at drying, the offset value corresponding to module 111 is +11 and the offset value corresponding to module 121 is +1. The “+” sign indicates an addition to the parameter setting value, whereas the “−” sign indicates a subtraction from the parameter setting value. Thus, the rotation speed at drying for module 111 is 1390 (obtained by adding 11 to 1379), and for module 121 it is 1380.

Referring back to FIG. 3, the selection unit 133 is configured to select one module from among the plurality of modules 111 to 124. For example, the selection unit 133 may select one module in response to an input from a user. Alternatively, the selection unit 133 may select one module according to a predetermined processing schedule.

The offset value extraction unit 134 is configured to extract, from among the plurality of offset values, the offset value corresponding to the module selected by the selection unit 133. For example, the offset value extraction unit 134 extracts, from the offset table OT1, the offset value associated with the identification information of the module selected by the selection unit 133. For example, if the selection unit 133 has selected module 111, the offset value extraction unit 134 extracts “+11” as the offset value for the rotation speed at drying.

The recipe generator 135 is configured to generate, based on the reference recipe RP1 and the extracted offset value, a process recipe to be executed by the selected module. The recipe generator 135 is configured to set the parameter setting value of the process recipe at a value obtained by adding the extracted offset value to the parameter setting value of a control parameter in the reference recipe RP1. For example, the recipe generator 135 generates a process recipe that includes 1390 as the rotation speed at drying, which is obtained by adding +11 (the offset value corresponding to module 111) to 1379 that is the rotation speed at drying in the reference recipe RP1. The generated process recipe is output to the substrate processing control unit 110. Based on the process recipe, the substrate processing control unit 110 carries out liquid processing on the wafer W.

The controller 100 may further include an offset editing unit 136. The offset editing unit 136 is configured to edit the offset table stored in the offset storage unit 132. For example, the offset editing unit 136 is configured to change the offset values for each module in the offset table.

The offset editing unit 136 may change two or more offset values in the offset table by an identical change amount. For instance, the offset editing unit 136 may change two or more offset values belonging to the same group by the identical change amount, based on a constraint condition. The constraint condition is, for example, a condition defined in advance so as to group the plurality of offset values into one or more groups in the offset table OT1. Because two or more offset values belonging to the same group are changed by the identical change amount under that constraint, the constraint condition may be regarded as a condition that constrains the change amount of offset values.

The offset editing unit 136 may select a constraint condition from among a plurality of default constraint conditions defined in advance, and based on the selected constraint condition, change the two or more offset values belonging to the same group by the identical change amount. For example, the controller 100 may further include a condition storage unit 138 that stores the plurality of default constraint conditions. The offset editing unit 136 may select a constraint condition from among the plurality of default constraint conditions stored in the condition storage unit 138. In the plurality of default constraint conditions, each default constraint condition has a different number of groups. Referring to FIG. 7, an example of the default constraint conditions is described. The plurality of default constraint conditions include a first condition C1, a second condition C2, a third condition C3, and a fourth condition C4. From the first condition C1 to the fourth condition C4 in that order, the degree of constraint becomes larger, and the number of groups decreases.

The first condition C1 is a condition that places each of the plurality of modules 111 to 124 in an individual group. That is, if the first condition C1 is selected as the constraint condition, offset values can be changed individually on a module-by-module basis.

The second condition C2 is a condition that places two or more modules connected to a common source 62 among the plurality of modules 111 to 124, in one group. In the example of FIG. 4, modules 111 and 112 are connected to the common source 62A, modules 113 and 114 are connected to the common source 62B, modules 121 and 122 are connected to the common source 62C, and modules 123 and 124 are connected to the common source 62D. In that case, if the second condition C2 is selected as the constraint condition, modules 111 and 112 form one group, modules 113 and 114 form other one group, modules 121 and 122 form other one group, and modules 123 and 124 form other one group. For example, the plurality of modules 111 to 124 is grouped into the following four groups:
Group 2-1: modules 111, 112
Group 2-2: modules 113, 114
Group 2-3: modules 121, 122
Group 2-4: modules 123, 124

The third condition C3 is a condition that places two or more modules included in the same block in the processing station 3 among the plurality of modules 111 to 124, into one group. In the example of FIG. 4, modules 111 to 114 included in the first block G11 form one group, and modules 121 to 124 included in the first block G12 form other one group. For example, the plurality of modules 111 to 124 is grouped into the following two groups:
Group 3-1: modules 111 to 114
Group 3-2: modules 121 to 124

The fourth condition C4 is a condition that places all the plurality of modules 111 to 124 in one group. In the example of FIG. 7, modules 111 to 124 all form one group.

The offset editing unit 136 may further include an offset changing unit 137. The offset changing unit 137 is configured to cause each of the plurality of modules 111 to 124 to execute processing according to a process recipe. The offset changing unit is further configured to change the offset table based on a plurality of processing results obtained by the plurality of modules 111 to 124 and on the constraint condition. For example, the offset changing unit 137 is configured to cause the selection unit 133 to sequentially select the plurality of modules 111 to 124. According to the module selection by the selection unit 133, the offset value extraction unit 134 extracts offset values, and the recipe generator 135 generates a process recipe, which is output to the substrate processing control unit 110. This results in execution of the process defined by the process recipe, and the film thickness as an example of the processing result is estimated by the film thickness calculation unit 120.

The offset changing unit 137 obtains multiple estimation results for the film thickness of the processed film as the processing results from the plurality of modules 111 to 124. The offset changing unit 137 changes the offset table OT1 based on the plurality of processing results by the plurality of modules 111 to 124 and the constraint condition. The offset changing unit 137 may repeatedly cause each of the plurality of modules 111 to 124 to execute processing while changing the constraint condition so as to reduce the number of groups, and may repeatedly update the offset table OT1.

For example, the offset changing unit 137, under the constraint condition that places each of the plurality of modules 111 to 124 in an individual group (e.g., the first condition C1), modifies the offset table OT1 so as to reduce a difference among the plurality of processing results, and under the constraint condition that places all of the plurality of modules 111 to 124 in the same group (e.g., the fourth condition C4), modifies the offset table OT1 so as to bring an average of the plurality of processing results closer to a target.

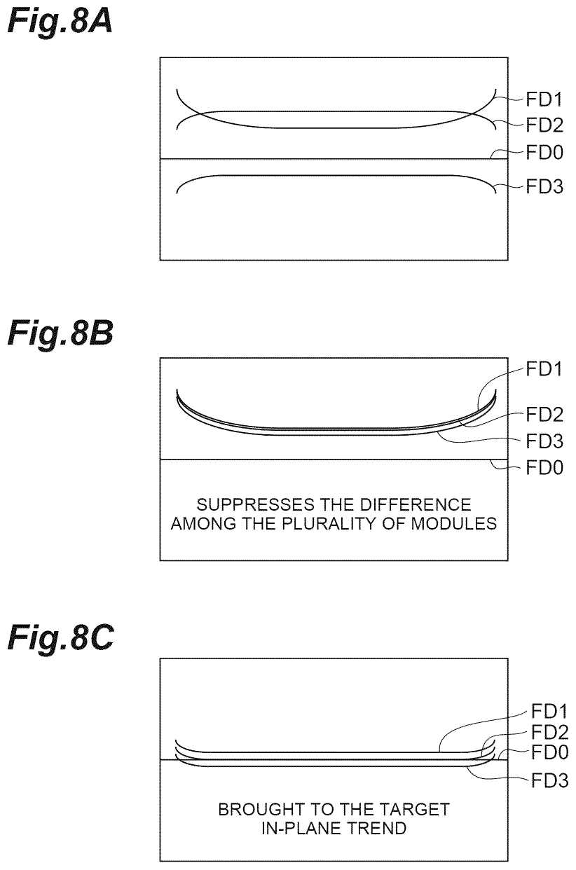

Here, referring to FIG. 8A, FIG. 8B, FIG. 8C, as an illustrative example, changing offset values for three modules among the plurality of modules 111 to 124 is described. In FIG. 8A, the relationship between the film thickness distributions FD1 to FD3 on the wafer W after being processed by different modules and the target value FD0 is shown. Because the trends of the film thickness distributions FD1 to FD3 differ from each other, merely bringing the film thickness average for each wafer W close to FD0 by changing offset values may leave differences in the trends in film thickness distribution.

In such a case, as shown in FIG. 8B, the offset changing unit 137 first suppresses the difference in the film thickness distributions among the plurality of modules 111 to 124. For example, using the first condition C1, the offset changing unit 137 changes the offset values for each of the plurality of modules 111 to 124 individually so that the film thickness distributions FD1 to FD3 exhibit a common average film thickness and an in-plane trend. The in-plane trend may refer, for instance, to the planar flatness or surface roughness in each of the film thickness distributions FD1 to FD3. Then, using the fourth condition C4, the offset changing unit 137 changes the offset values for each of the plurality of modules 111 to 124 by the identical amount so that the average film thickness of each wafer W approximates the target value FD0, and the in-plane trend becomes the target. The target in-plane trend may be stored in advance in the condition storage unit 138 or may be set by the user. In this manner, as shown in FIG. 8C, while the film thickness distributions FD1 to FD3 are maintained with the same trend, the average film thickness of each wafer W is brought closer to the target value FD0, and their in-plane trend is brought to the target in-plane trend.

The offset changing unit 137 may change the constraint condition from the first condition C1 to the fourth condition C4 by sequentially going through the second condition C2 and the third condition C3. For example, the offset changing unit 137, under the first condition C1, modifies the offset table OT1 so as to reduce the difference among the processing results, and then may change the first condition C1 to the second condition C2. Under the second condition C2, the offset changing unit 137 modifies the offset table OT1 so as to reduce the differences among groups 2-1 to 2-4, and then may change from the second condition C2 to the third condition C3. Under the third condition C3, the offset changing unit 137 may modify the offset table OT1 so as to reduce the differences among groups 3-1 and 3-2, and then changes the third condition C3 to the fourth condition C4. Under the fourth condition C4, the offset changing unit 137 modifies the offset table OT1 so that the average and the in-plane trend of the plurality of processing results approach the target.

As shown in FIG. 7, the recipe storage unit 131 may further store a source recipe RP2 in association with the sources 62A to 62D. The source recipe RP2 includes a stop timing for supply of the processing liquid (a third setting value) and a discharge pressure for the processing liquid (a fourth setting value). The recipe storage unit 131 may store a source recipe RP2 for each of the plurality of sources 62A to 62D. For example, the recipe storage unit 131 may store a plurality of source recipes RP2 respectively corresponding to the plurality of sources 62A to 62D. The stop timing of the processing liquid supply is, for example, a timing at which the on-off valve 64 is switched to a closed state from a state in which the processing liquid is supplied to wafer W. Switching the on-off valve 64 to the closed state stops supplying the processing liquid from the nozzle. Both the third setting value and the fourth setting value affect the in-plane distribution of the film thickness on wafer W.

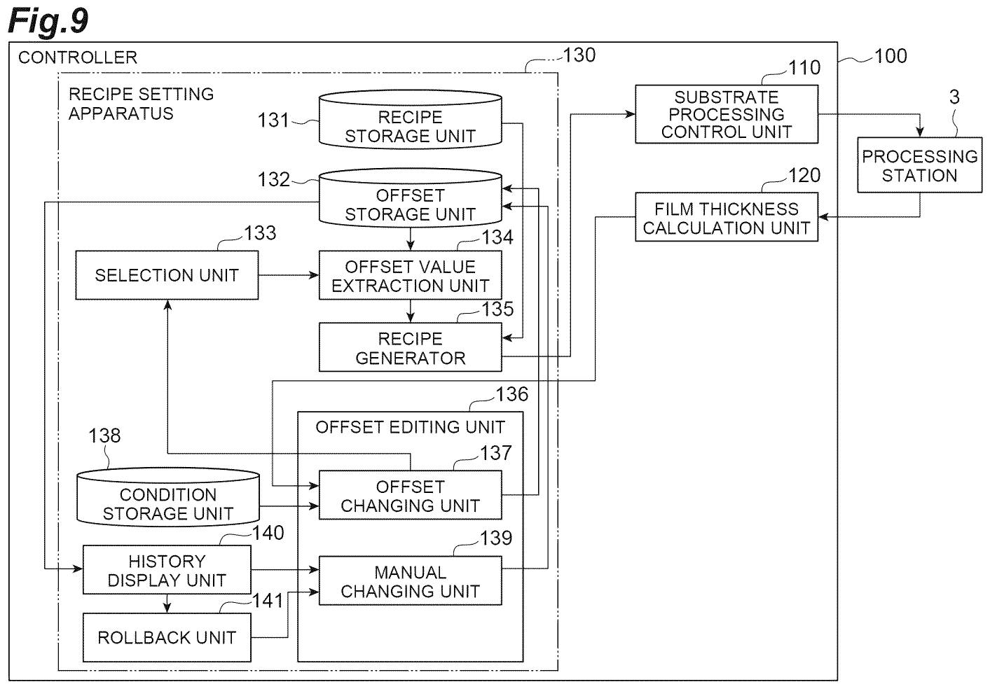

As shown in FIG. 9, the offset editing unit 136 may further include a manual changing unit 139. The manual changing unit 139 is configured to change the offset table OT1 based on user input. The manual changing unit 139 may be used when a user wants to change the process recipe manually in response to changes in external environment, for example. The manual changing unit 139 may generate an input interface that lists the plurality of offset values in association with each of the plurality of modules. The input interface is displayed by, for example, a display unit provided in the controller 100. In that case, from the list of offset values shown on the input interface, the user selects a record of the module to be adjusted, and changes the offset value on the input interface. In response to the plurality of offset values being changed in the input interface, the manual changing unit 139 may change the offset table OT1 accordingly.

The recipe setting apparatus 130 further includes a history display unit 140 and a rollback unit 141. The history display unit 140 is configured to display, on the input interface, a change history of the offset table OT1 made by the manual changing unit 139. The change history may, for instance, include a list of multiple change records in time series. Each change record among the multiple records may include time of change, the module to be changed, the parameter to be changed, correction value used for the change, the offset value before correction, and the offset value after correction.

The rollback unit 141 restores the offset table OT1 to a past state selected from the change history. For example, when one of the change records in the change history is selected by the user, the rollback unit 141 changes the parameter to be changed for the module targeted by that change record back to the offset value included in that change record.

The manual changing unit 139 may be configured so that one offset table can be associated with multiple reference recipes. For example, the manual changing unit 139 may further generate a second input interface that displays, in association with the offset table OT1, a recipe list including the reference recipe RP1. The second input interface is displayed by the display unit. The manual changing unit 139 associates another reference recipe with the offset table OT1, in response to the other reference recipe is added to the recipe list in the second input interface. In this manner, the offset table OT1 generated for one reference recipe can be reused for the other reference recipe. This can reduce the workload of generating the offset table OT1.

The manual changing unit 139 may generate a candidate list including one or more reference recipes that can be added to the recipe list, in response to a selection of the offset table OT1. The manual changing unit 139 may then add one reference recipe selected from the candidate list to the recipe list as that other reference recipe. For example, on the second input interface, the user selects, as the other reference recipe, a new reference recipe from among the candidate list, to be added to the recipe list.

A situation in which the offset table OT1 for one reference recipe can be reused for another reference recipe, for example, is a situation where the one reference recipe and the other reference recipe target an identical module and include an identical control parameter. In particular, if the value of that “identical control parameter” in the one reference recipe is the same as or similar to the value of the corresponding parameter in the other reference recipe, there is a likelihood that the offset table OT1 can be reused. Therefore, the manual changing unit 139 may generate the candidate list that includes one or more reference recipes each having parameter setting value (item value) for the control parameter corresponding to the plurality of offset values, in common with those in the reference recipe RP1. That is, the manual changing unit 139 may add to the candidate list one or more reference recipes that include a parameter setting value in common with at least one control parameter in the reference recipe RP1. For example, if the parameter setting value of the rotation speed at drying in the reference recipe RP1 is shared (e.g., identical) with the parameter setting values of the rotation speed at drying in the one or more reference recipes, the manual changing unit 139 includes the one or more reference recipes in the candidate list. The control parameters other than the rotation speed at drying may differ from those in the reference recipe RP1 in one or more reference recipes.

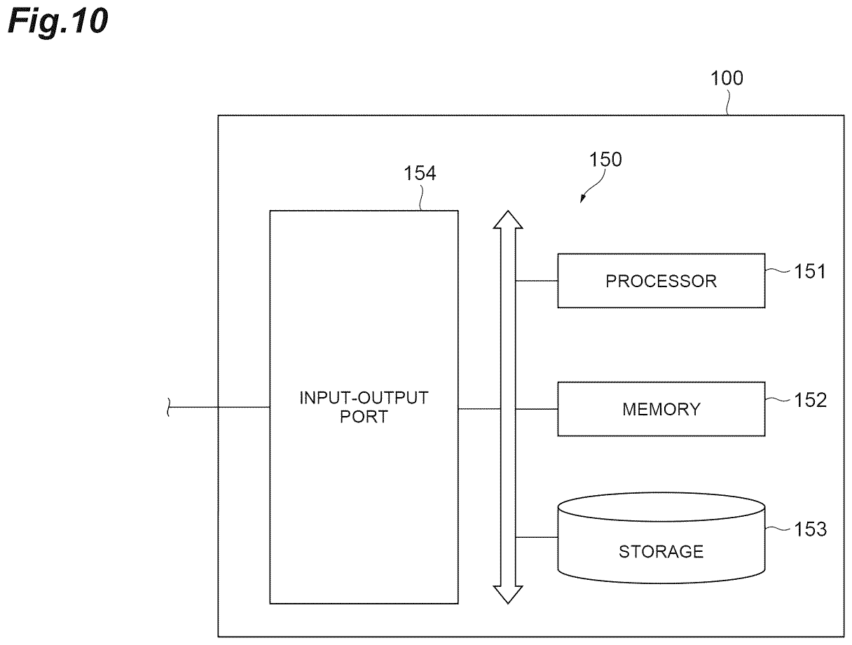

The above-described controller 100 can be configured by one or more control computers. FIG. 10 is a diagram showing an example hardware configuration of the controller 100. For example, the controller 100 has circuitry 150 shown in FIG. 10. The circuitry 150 includes one or more processors 151, a memory 152, a storage 153, and an input-output port 154. The storage 153 may have a computer-readable storage medium, such as a hard disk. The storage medium stores a program for causing the controller 100 to execute the substrate processing method and the film thickness estimation method described below. The storage medium may also be a removable medium such as a nonvolatile semiconductor memory, a magnetic disk, or an optical disk.

The memory 152 temporarily stores the program loaded from the storage medium of the storage 153, as well as computation results of the processor 151. By cooperating with the memory 152, the processor 151 executes the above program to construct the respective functional modules described above. The input-output port 154 inputs and outputs electric signals from and to each component of the processing station 3 in accordance with instructions from the processor 151.

The controller 100 may be constituted by a plurality of control computers. For example, at least the substrate processing control unit 110 and the film thickness calculation unit 120 may be configured by one or more control computers, and the recipe setting apparatus 130 may be configured by another computer that is communicable with the aforementioned one or more control computers. Note that the hardware configuration of the controller 100 may not be limited to the arrangement in which the functional modules are formed by programs. For example, each functional module of the controller 100 may be constituted by dedicated logic circuits or an ASIC (Application Specific Integrated Circuit) in which such circuits are integrated.

### [Recipe Setting Procedure]

Next a recipe setting procedure by the recipe setting apparatus 130 is described as an example recipe setting method. The recipe setting procedure includes: storing a reference recipe; storing, in association with the reference recipe, an offset table that includes a plurality of offset values respectively corresponding to a plurality of modules; selecting one module from the plurality of modules; extracting from the plurality of offset values the offset value corresponding to the selected module; and generating, based on the reference recipe and the extracted offset value, a process recipe to be executed by the selected one module. The procedure may further include causing the selected device to execute the process on the substrate according to the generated process recipe. Causing may be transmitting the generated process recipe to the substrate processing control unit 110 to execute the process according to the generated process recipe. The example recipe setting procedure below includes an automatic editing procedure for the offset table, a manual editing procedure for the offset table, and a procedure for generating a process recipe. Below, each procedure is described in detail.

### (Automatic Editing Procedure for Offset Table)

This procedure is executed under a state in which the offset storage unit 132 has already stored the offset table. The offset table stored in the offset storage unit 132 may be an initial table in which each offset value among the plurality of offset values is initially set to, for example, zero.

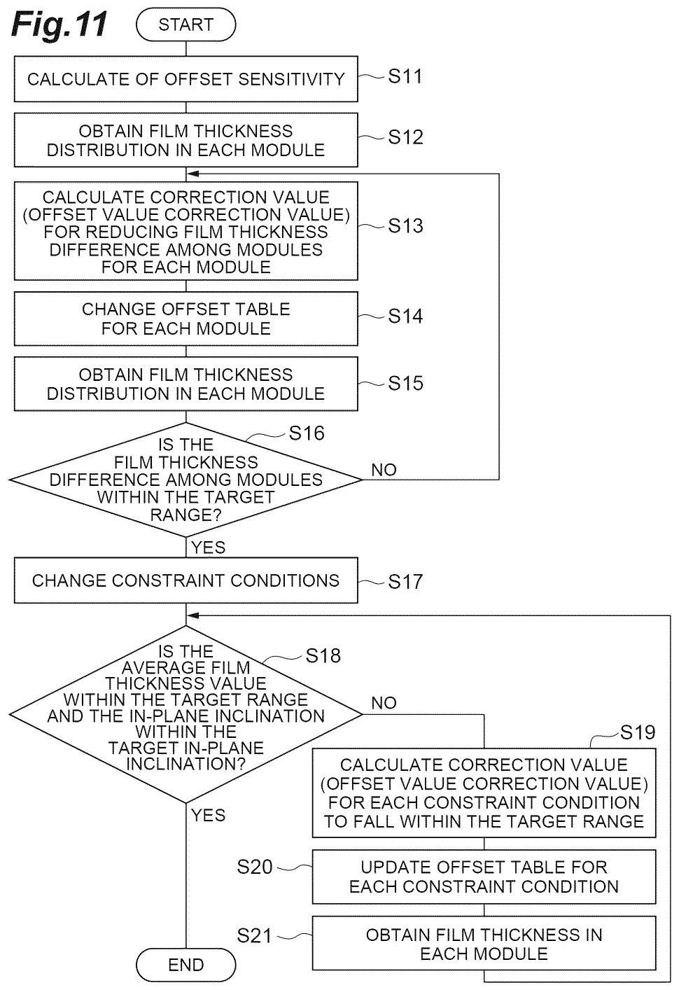

As shown in FIG. 11, the recipe setting apparatus 130 first performs operation S11. In operation S11, the offset changing unit 137 calculates an offset sensitivity. The offset sensitivity is information that represents the relationship between an offset value and the film thickness in one module among the plurality of modules 111 to 124. By obtaining the offset sensitivity in advance, how much the offset value should be changed to modify the film thickness distribution may be estimated more precisely.

The relationship between the offset value and the film thickness distribution may be grasped based on experimental data on how the film thickness will change when the offset value is varied in one module among the plurality of modules 111 to 124. To calculate the sensitivity of each offset value, experimental conditions are extracted first. For example, using known design-of-experiments methods or the like, experimental conditions can be selected, and an experimental condition table can be prepared.

The offset changing unit 137 sequentially changes offset values based on the prepared experimental condition table. Every time an offset value is changed, the offset changing unit 137 causes the selection unit 133 to select the one module mentioned above. In response to the module selection by the selection unit 133, the offset value extraction unit 134 extracts the offset value, and the recipe generator 135 generates the process recipe, which is then output to the substrate processing control unit 110. This causes execution of the processing defined by the process recipe, and the resultant film thickness distribution as an example of the processing result is estimated by the film thickness calculation unit 120. By correlating the experimental condition table and these measurement results (experimental results) of film thickness distribution, the offset changing unit 137 obtains the offset sensitivity that indicates how each offset value contributes to the film thickness distribution of the processed film.

From the measurement results of the film thickness distribution, a feature quantity representing the film thickness distribution is obtained. In one example, the feature quantity representing the film thickness distribution may be determined by approximating it with Zernike polynomials, and adopting a coefficient for each term as the feature quantity.

The offset changing unit 137 calculates the correlation between the feature quantities obtained from the measurement result of film thickness distribution approximated by the Zernike polynomials, and each offset value. For example, the offset changing unit 137 grasps how much the weighting coefficients in the Zernike polynomials change when the offset value is changed by a predetermined amount, and as a result, how much the film thickness distribution changes. That result can serve as the offset sensitivity.

Next, the recipe setting apparatus 130 executed operation S12. In operation S12, the offset changing unit 137 obtains the film thickness distribution of wafer W after processing by each of the plurality of modules 111 to 124. For instance, the offset changing unit 137 sets the offset values for each of the modules 111 to 124 to zero, then causes the selection unit 133 to select the modules 111 to 124 in turn. Corresponding to a module selection by the selection unit 133, the offset value extraction unit 134 extracts an offset value, and the recipe generator 135 generates a process recipe, which is output to the substrate processing control unit 110. Thus, the process is executed according to that process recipe, and the film thickness distribution as an example of the processing result is estimated by the film thickness calculation unit 120. The offset changing unit 137 obtains the estimated result from the film thickness calculation unit 120 as the film thickness distribution of wafer W after processing by each of the plurality of modules 111 to 124.

In operation S13, based on the film thickness distributions obtained in operation S12 and the offset sensitivity calculated in operation S11, the offset changing unit 137 calculates correction values (correction values for the offset values) to reduce the difference in the film thickness distribution (hereafter referred to as “film thickness difference”) among the plurality of modules 111 to 124. For example, under the first condition C1, the offset changing unit 137 calculates the correction value individually for each module. For example, the offset changing unit 137 may determine a correction value for correcting a bias in the film thickness distribution by setting up a Type I quantification problem, for example, and solving it with a known method, calculating the correction value for each module.

In operation S14, the offset changing unit 137 changes each module's offset value in the offset table OT1 stored in the offset storage unit 132 by the correction value calculated in the operation S13. For example, the offset changing unit 137 adds the correction value to each module's offset value.

In operation S15, as in operation S12, the offset changing unit 137 obtains the film thickness distribution of wafer W after processing by each of the plurality of modules 111 to 124.

In operation S16, the offset changing unit 137 determines whether the film thickness difference among the modules 111 to 124 is within a target range. If the film thickness difference between modules 111 to 124 is not within the target range (operation S16-NO), the recipe setting apparatus 130 returns procedure to operation S13. Henceforth, until the film thickness difference among the modules 111 to 124 enters the target range, changing the offset value and checking for whether the film thickness difference is within that target range are repeated.

If the film thickness difference is within the target range (operation S16—YES), the recipe setting apparatus 130 performs operations S17 and S18. In operation S17, the offset changing unit 137 changes the constraint condition. The offset changing unit 137 chooses one of the second to fourth conditions C2 to C4, which are the default constraint conditions stored in the condition storage unit 138. For example, the offset changing unit 137 changes the first condition C1 to the fourth condition C4.

In operation S18, the offset changing unit 137 determines whether the average value of film thickness obtained is within the target range, and whether the in-plane trend of each module among modules 111 to 124 has reached the target. In this operation, the offset changing unit 137, for example, calculates the average value of the film thickness among the plurality of modules 111 to 124. The target range may be, for example, a range obtained by adding a predetermined value in the positive direction and subtracting the same in the negative direction from the target value FD0. Whether the in-plane trend has reached the target may be determined, for example, based on whether 3 σ of the difference between each module's in-plane trend value and the in-plane trend's target has reached a reference value. Whether the in-plane trend has reached the target may be whether a range from minimum to maximum of the difference has reached a reference range. Alternatively, it may be determined by whether the 3 σ of each module's in-plane trend value has reached the reference value or whether the range from the minimum to the maximum value of each module's in-plane trend value has reached the reference range

If the average film thickness and in-plane trend are not within the target range (operation S18—NO), the recipe setting apparatus 130 performs operations S19, S20, and S21. In operation S19, under the fourth condition C4, the offset changing unit 137 calculates one correction value for the plurality of modules 111 to 124. For example, based on the average film thickness and the offset sensitivity, the offset changing unit 137 calculates an identical correction value (correction value for the offset) to bring the average film thickness within the target range. In operation S20, the offset changing unit 137 updates the offset table OT1 by adding the identical correction value to each offset value among the plurality of offset values stored in the offset storage unit 132. In operation S21, as in operation S13, the offset changing unit 137 obtains the wafer W film thickness value (for instance the average film thickness in wafer W's plane) after processing by each of the plurality of modules 111 to 124. After that, the recipe setting apparatus 130 returns procedure to operation S18.Operations S18 to S21 are repeated until the average film thickness enters the target range. If the average film thickness is within the target range (operation S18—YES), the series of processes ends. Note that the recipe setting apparatus 130 may omit operation S18. In that case, regardless of whether the average film thickness and the in-plane trend are within the target range, the recipe setting apparatus 130 may proceed to execute operations S19, S20, and S21.

### (Manual Editing Procedure for the Offset Table)

This procedure further edits the offset table, after the auto-edit procedure described above, based on manual user input. For example, this procedure is performed if changes in the external environment make it so that, even with the already edited offset table, the film thickness difference or the average film thickness no longer stays within the target range. Also, according to this procedure, the initial table may manually be edited based on user input without the above auto-edit procedure.

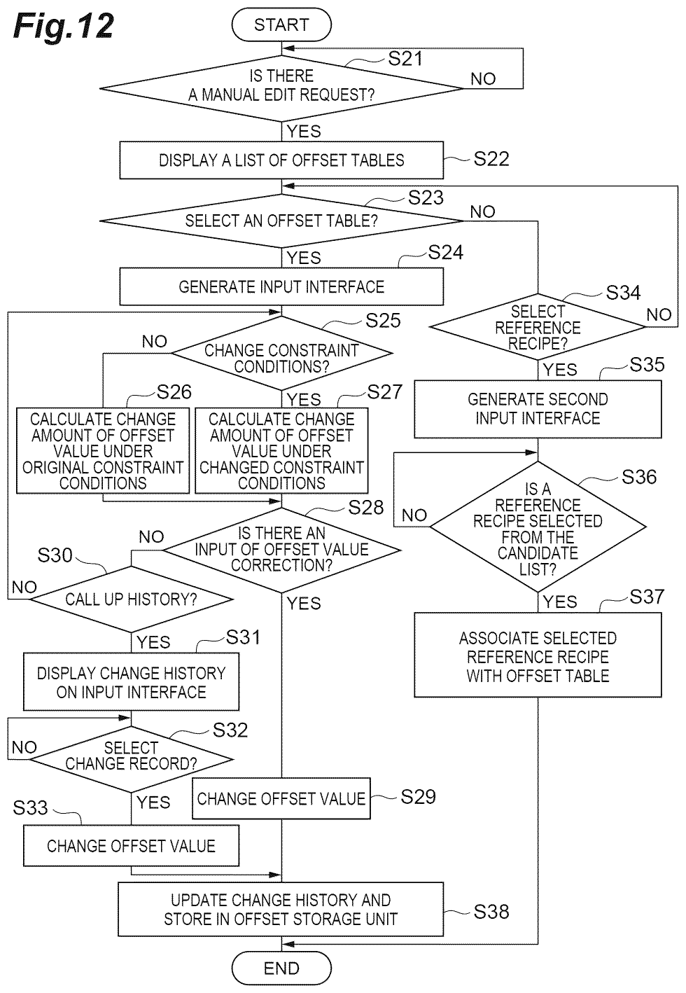

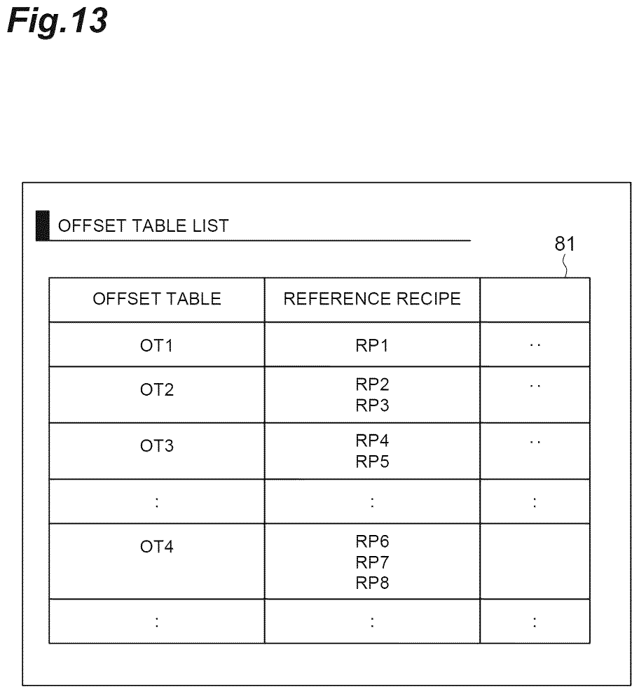

As depicted in FIG. 12, the recipe setting apparatus 130 executes operations S21 and S22. In operation S21, the manual changing unit 139 waits for a user request to perform manual editing. In operation S22, the manual changing unit 139 displays, on a display unit, a list of offset tables. FIG. 13 shows one example of an offset table list 81. The offset table list 81 displays a plurality of offset tables and a reference recipe corresponding to each of the plurality of offset tables, in a list.

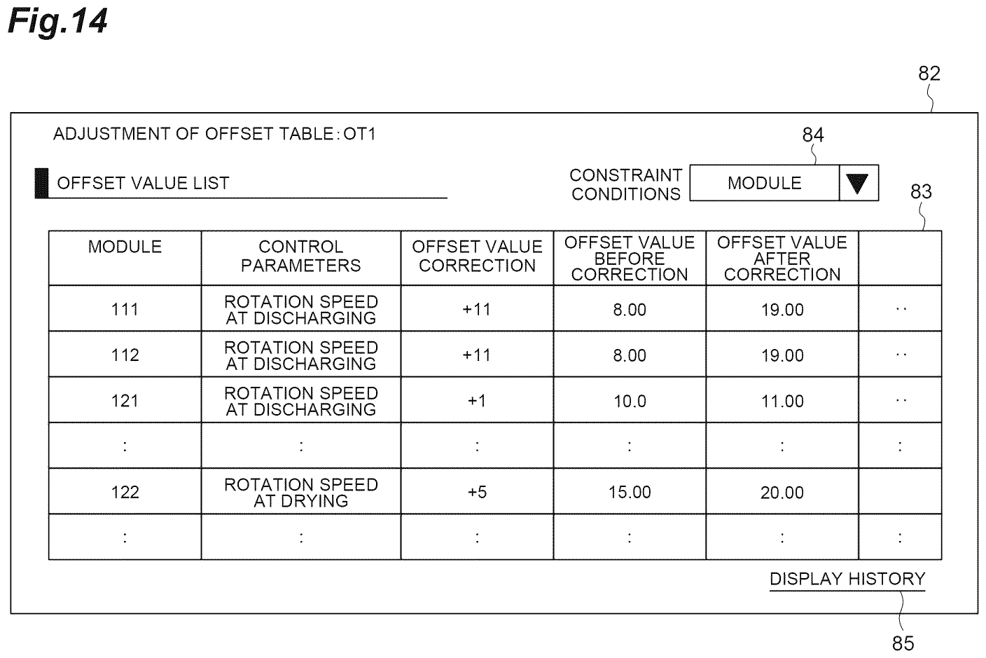

Returning to FIG. 12, the recipe setting device 130 next executes operation S23. In operation S23, the manual changing unit 139 determines whether any offset table in the offset table list 81 is selected. If an offset table is selected (operation S23—YES), then in operation S24, the manual changing unit 139 generates an input interface. FIG. 14 shows an example of an input interface 82. FIG. 14 depicts the input interface 82 generated when the offset table OT1 is selected in operation S23. In FIG. 14, the input interface 82 includes an offset value list 83. The offset value list 83 lists, in association with each of the plurality of modules 111 to 124, a control parameter, a correction value for the offset, the offset value before correction, and the offset value after correction. The input interface 82 may also include an input section 84 for specifying a constraint condition. The input section 84 may provide a pull-down menu for selecting from a plurality of default constraint conditions. The input interface 82 may further include a history call-up button 85 for displaying a change history.

Going back to FIG. 12, the recipe setting device 130 next executes operation S25. In operation S25, it is checked (for instance, via the input section 84) whether the constraint condition has been changed. If the constraint condition has been changed (operation S25—YES), the recipe setting device 130 executes operation S27. In operation S27, the offset changing unit 137 changes the constraint condition for the amount of change in the offset values, in accordance with the change made in the input section 84. If there has been no change in the constraint condition (operation S25—NO), then in operation S26, the offset changing unit 137 retains the original constraint condition.

After operations S26 and S27, the recipe setting device 130 executes operation S28. In operation S28 the manual changing unit 139 checks whether a newly entered correction value is present. In accordance with the correction value entered and the constraint condition, the manual changing unit 139 stores an offset value obtained by adding the correction value to the current offset value in the offset storage unit 132, treating that as the post-correction offset value.

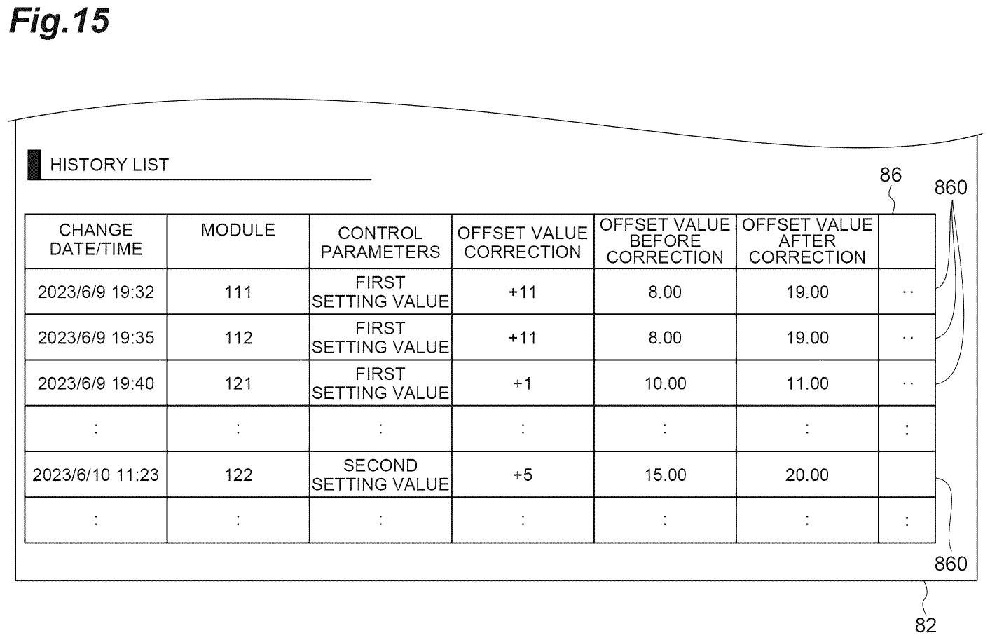

If no change in the offset value is entered (operation S28-NO), the recipe setting device 130 executes operation S30. In operation S30, the recipe setting apparatus 130 determines whether the user has performed an operation requesting a history call-up, by the manual changing unit 139. For example, at the input interface 82, the manual changing unit 139 checks whether the user has pressed the history call-up button 85. If no history call-up request is detected (operation S30—NO), the recipe setting apparatus 130 returns processing to operation S25. If a history call-up request is detected (operation S30—YES), the recipe setting apparatus 130 carries out operations S31, S32, and S33. In operation S31, the history display unit 140 displays a change history 86 on the input interface 82. FIG. 15 shows one example of a change history 86. The change history 86 is displayed, for instance, below the offset value list 83 in the input interface 82. In FIG. 15, the change history 86 includes a plurality of change records 860 in time series. Each of the plurality of change records 860 includes a change date/time, a module to be changed, a parameter to be changed, a correction value used for the change, the offset value before correction, and the offset value after correction.

Returning to FIG. 12, in operation S32, the rollback unit 141 waits for one of the plurality of change records 860 in the change history 86 to be selected. In operation S33, the rollback unit 141 changes the parameter to be changed of the module targeted by the selected change record, to the offset value included in that change record.

After operations S29 or S33, the recipe setting apparatus 130 executes operation S38. In operation S38, the manual change unit 139 updates the change history 86 based on changing of the offset value carried out in operation S29 or operation S33. For example, the manual changing unit 139 may add to the change history 86 a change record that includes the details of the changes in operation S29 or S33.

If no offset table is selected in operation S23 (operation S23—NO), then the recipe setting device 130 executes operation S34. In operation S34, the manual changing unit 139 determines whether a reference recipe has been selected in the offset table. If it is determined that no reference recipe is selected in the offset table (operation S34—NO), the recipe setting apparatus 130 returns procedure to operation S23.

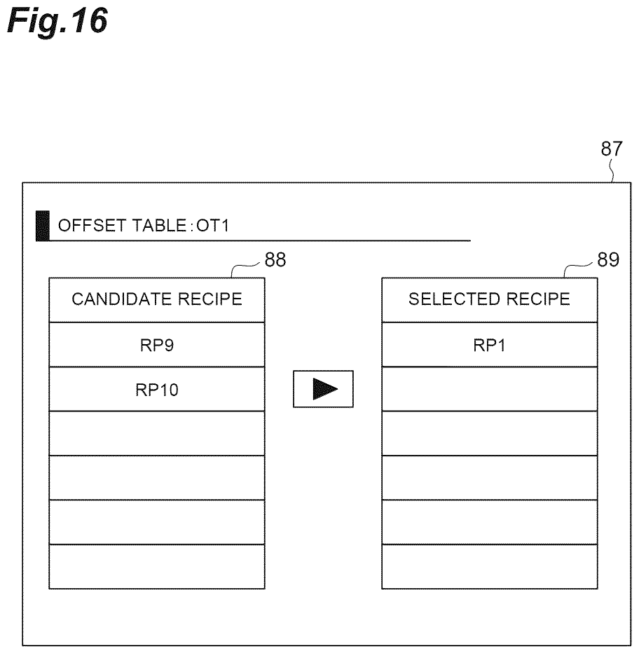

If, in operation S34, it is determined that a reference recipe has been selected (operation S34—YES), the recipe setting apparatus 130 performs operations S35, S36, and S37. In operation S35, the manual changing unit 139 generates a second input interface. FIG. 16 shows an example of a second input interface 87. In the example of FIG. 16, the second input interface 87 includes a candidate list 88 and a recipe list 89. The recipe list 89 lists reference recipes that have already been associated with the offset table OT1. In FIG. 16, the recipe list 89 shows the reference recipe RP1. The candidate list 88 is a list of one or more reference recipes that can be added to the recipe list 89.

In operation S36, the manual changing unit 139 waits for a selection of a reference recipe in the candidate list 88. In operation S37, the manual changing unit 139 associates the reference recipe selected from the candidate list 88 with the offset table as another reference recipe. The recipe setting apparatus 130 may end the manual editing procedure after operation S36 or S37, or may continue the manual editing procedure until an operation such as closing the offset table is performed.

### (Procedure for Generating a Process Recipe)

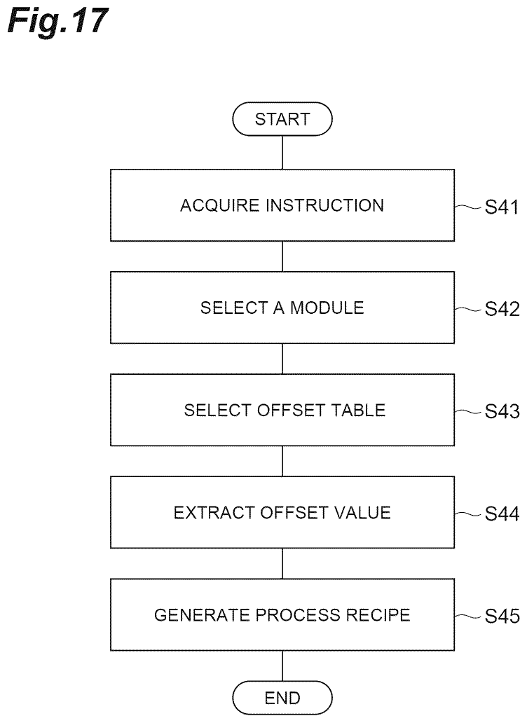

This procedure generates a process recipe based on the already generated offset table and the reference recipe. As shown in FIG. 17, the recipe setting apparatus 130 executes operations S41, S42, S43, S44, and S45.

In operation S41, the selection unit 133 receives, from a process operation instructing unit (not shown) provided in the controller 100, an instruction for executing a process. The execution instruction includes identification information of the process to be executed. In operation S42, the selection unit 133 selects one module from among the plurality of modules 111 to 124 that can perform the instructed process. In operation S43, the offset value extraction unit 134 selects, from an offset table associated with the instructed process's reference recipe.

In operation S44, the offset value extraction unit 134 extracts from the offset table OT1 the offset values corresponding to the module selected by the selection unit 133. In operation S45, the recipe generator 135 generates a process recipe to be executed by the selected one module, based on the reference recipe RP1 and the extracted offset value. The substrate processing control unit 110 carries out liquid processing on the wafer W in accordance with the process recipe generated in operation S45.

### (Monitoring Changes Over Time in a Plurality of Offset Values)

The offset storage unit 132 may store the plurality of offset values for each of a plurality of points in time. For example, each time the offset changing unit 137 updates the offset table OT1 by adding a correction value to each offset value among the plurality of offset values, it may store those updated offset values in the offset storage unit 132. The offset changing unit 137 may perform such updates of the offset table OT1 during periodic maintenance of the controller 100. In such a case, each of the plurality of points in time is a time when the control device 100 is under a periodic maintenance. For example, the maintenance of the control device 100 may be performed daily, monthly, or once every few months.

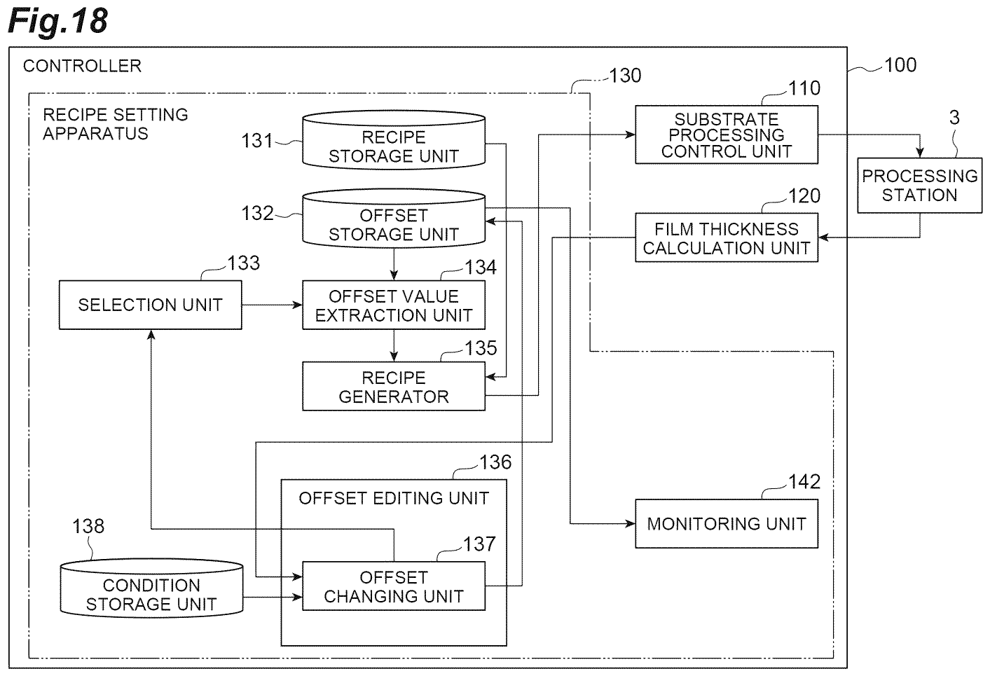

If the offset storage unit 132 stores, for each of a plurality of points in time, the plurality of offset values, then as shown in FIG. 18, the recipe setting apparatus 130 may further include a monitoring unit 142. The monitoring unit 142 may generate a monitoring interface that displays a temporal transition of the plurality of offset values based on the plurality of offset values at each of the plurality of points in time. Form of display of the changes over time of the plurality of offset values may be in any form.

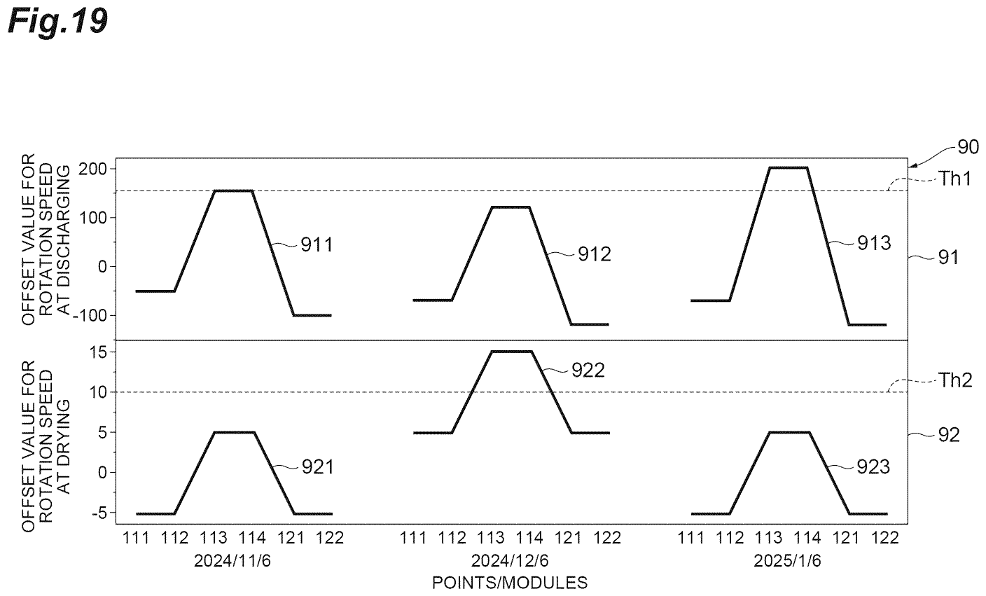

As one example, as shown in FIG. 19, the monitoring unit 142 generates a monitoring interface 90 that displays a graph representing the temporal transitions of the plurality of offset values. In FIG. 19, the monitoring unit 142 displays in the monitoring interface 90 both a graph 91 representing the temporal transitions of the plurality of offset values for the rotation speed at discharging (the first setting value) and a graph 92 representing the temporal transitions of the plurality of offset values for the rotation speed at drying (the second setting value). The rotation speed at discharging may be, for example, the rotation speed of wafer W while the processing liquid is being discharged from the nozzle 61, which contributes to the in-plane distribution of the film thickness of the processing liquid. The rotation speed at drying may be, for example, the rotation speed of wafer W after the discharge of the processing liquid from the nozzle 61 is stopped, which contributes to the average film thickness measured at multiple locations on the wafer W. The horizontal axis of the graphs 91 and 92 represent the plurality of points in time, and the example in FIG. 19 shows calendar dates. The horizontal axis of graph 91 may be the same as that of graph 92. The vertical axis of graph 91 represents the rotation speed at discharging, while the vertical axis of graph 92 represents the rotation speed at drying. In the example of FIG. 19, graph 91 and graph 92 are displayed one above the other in the monitoring interface 90, but the graph 91 and the graph 92 may be displayed side by side.

In addition, the monitoring unit 142 may generate in the monitoring interface 90 a graph 91 that includes sub-graphs 911, 912, and 913 for individually showing the plurality of offset values at each of the plurality of points in time. The sub-graphs 911, 912, and 913 correspond to different points in time respectively. The horizontal axis of each sub-graph 911, 912, and 913 indicates an arbitrary one of the plurality of modules 111 to 124. In the example of FIG. 19, multiple modules 111 to 122 are displayed. The vertical axis of each sub-graph 911, 912, and 913 indicates the offset value for the rotation speed at discharging.

By using the monitoring interface 90 generated by the monitoring unit 142, the user may monitor changes in the plurality of offset values over time from the graph 91. Also, from each of the sub-graphs 911, 912, and 913, the user may monitor how the variation among the offset values for the plurality of modules 111 to 122 changes over time. For example, the user may first note in graph 91 that the plurality of offset values increase from 2024 Dec. 6 to 2025 Jan. 6. Then, from sub-graphs 912 and 913, the user may observe that the variation among the plurality of offset values is also increasing, and particularly that the offset values for modules 113 and 114 have increased more than for other modules.

The monitoring unit 142 may arrange the display of graph 91 and its sub-graphs 911, 912, and 913so that they can be distinguished in the monitoring interface 90. For example, the monitoring unit 42 may display each sub-graph with a gap between the sub-graph 911 and the sub-graph 912, and with a gap between the sub-graph 912 and the sub-graph 913. As shown in FIG. 19, the monitoring unit 42 may display each of sub-graph 911, sub-graph 912, and sub-graph 913 as a line chart, with a gap between the sub-graphs.

The monitoring unit 142 may provide at least one of an upper-limit threshold value and a lower-limit threshold value in the monitoring interface 90. If any offset value exceeds the upper-limit threshold or goes below the lower-limit threshold, the monitoring unit 142 may alert the user to an abnormal condition. For instance, in the example of FIG. 19, the monitoring unit 142 provides an upper-limit threshold Th1 in graph 91. Because in sub-graph 913 the offset values of modules 113 and 114 exceed Th1, the monitoring unit 142 alerts the user.

Similarly, the monitoring unit 142 may generate the monitoring interface 90 to display the graph 92 including sub-graphs 921, 922, and 923 for showing the plurality of offset values individually at each point in time. The sub-graphs 921, 922, and 923 are, except that their vertical axes indicate the rotation speed at drying, the same as the sub-graphs 911, 912, and 913. In the example of FIG. 19, the monitoring unit 142 sets a threshold Th2 in graph 92. If, for instance, in sub-graph 922 the offset values of modules 113 and 114 exceed Th2, the monitoring unit 142 alerts the user. As one example of alerting, the monitoring unit 142 may display the alert prominently on the monitoring interface 90 or on another interface, or emit a warning sound in addition to or in place of the display.

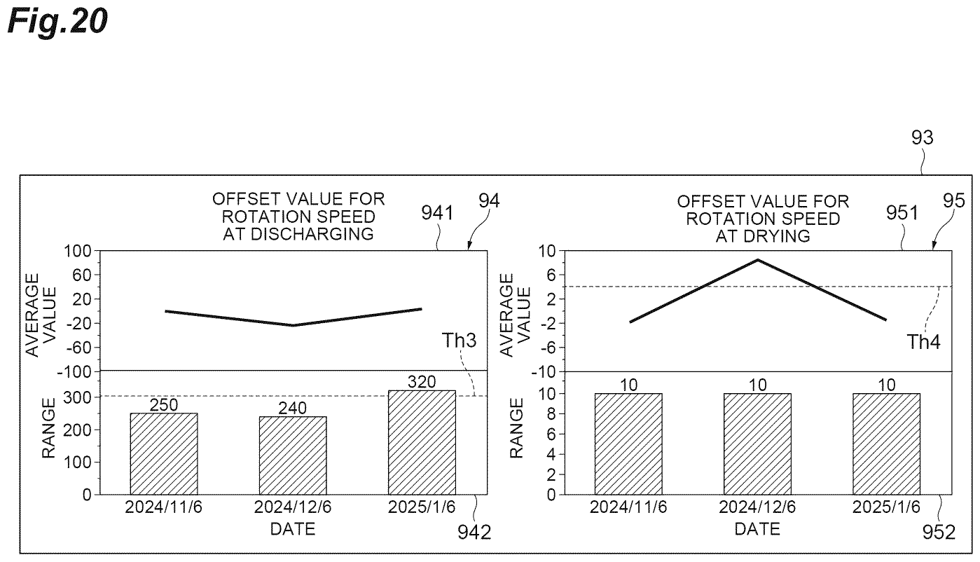

The monitoring unit 142 may generate a monitoring interface representing a temporal transition of statistical values of the plurality of offset values. The statistical values may include at least one of the average value, median, and dispersion measure of the plurality of offset values. The dispersion measure may be a standard deviation or 3 σ, which is three times the standard deviation, or a dispersion range. The dispersion range is, for example, the difference between the minimum and maximum offset values among multiple offset values. The monitoring unit 142 may display multiple statistical values for each of the plurality of points in time. By way of example, as shown in FIG. 20, the monitoring unit 142 generates a monitoring interface 93 that displays the temporal transitions of both the average and the dispersion measure of the plurality of offset values. Here, the “dispersion measure” indicates the range between the minimum and the maximum among the plurality of offset values at each point in time. In the example of FIG. 20, the monitoring unit 142 displays both a graph 94 representing an average value and a range of the plurality of offset values for the rotation speed at discharging, and a graph 95 representing an average value and a range of the plurality of offset values for the rotation speed at drying on the monitoring interface 93. In FIG. 20, graph 94 and graph 95 are displayed side by side on the monitoring interface 93, but they can also be placed one above the other.

Furthermore, the monitoring unit 142 may generate the monitoring interface 93 that displays a graph 94 including a sub-graph 941 for showing the average value of the plurality of offset values and a sub-graph 942 for showing the range of the plurality of offset values, and similarly a graph 95 including a sub-graph 951 and a sub-graph 952. Sub-graphs 941 and 951 represent average values of multiple modules at each of the plurality of points in time. Sub-graphs 942 and 952 represent ranges of multiple modules at each of the plurality of points in time. The horizontal axis of each sub-graph 941, 951, 942, and 952 corresponds to the plurality of points in time, for which calendar dates are shown in the example of FIG. 20. The form of display of the monitoring interface 93 is not limited to the example in FIG. 20. For example, sub-graphs 941 and 951 are displayed as line graphs, but bar graphs could also be used.

The monitoring unit 142 may include an upper-limit threshold and/or lower-limit threshold in the monitoring interface 93. If a statistical value among the plurality of offset values exceeds the maximum threshold value or falls below the minimum threshold value, the monitoring unit 142 may alert the user to an abnormal condition. For example, in FIG. 20, the monitoring unit 142 sets an upper-limit threshold Th3 in sub-graph 942. Because the range at the point in time of 2025 Jan. 6 in sub-graph 942 exceeds Th3, the monitoring unit 142 alerts the user. Additionally, the monitoring unit 142 sets an upper-limit threshold Th4 in sub-graph 951. Because the range at the point in time of 2024 Dec. 6 in sub-graph 951 exceeds Th4, the monitoring unit 142 alerts the user.

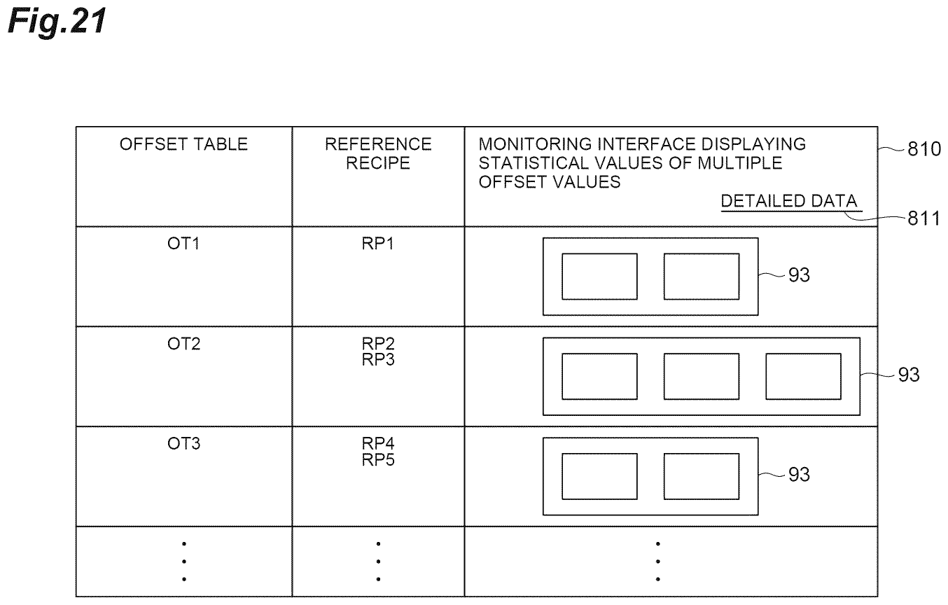

After checking the temporal transitions of the statistical values of the plurality of offset values on the monitoring interface 93, the user may call up the monitoring interface 90 to check more detailed data on the temporal transitions of the offset values themselves. For example, as shown in FIG. 21, the offset changing unit 137 may display on the display unit the offset table list 810 containing the monitoring interface 93. The offset table list 810 shows a plurality of offset tables, their corresponding reference recipes, and the monitoring interfaces 93 corresponding to these offset tables, in a list. The number of sub-graphs displayed in the monitoring interface 93 may be two or more, and the number of statistical values that can be displayed in each sub-graph may be two or more.

The user can first check the temporal transitions of the statistical values of the plurality of offset values shown by the monitoring interface 93 from the offset table list 810, and then press a detail-data call-up button 811 to call up the monitoring interface 90 shown in FIG. 19.

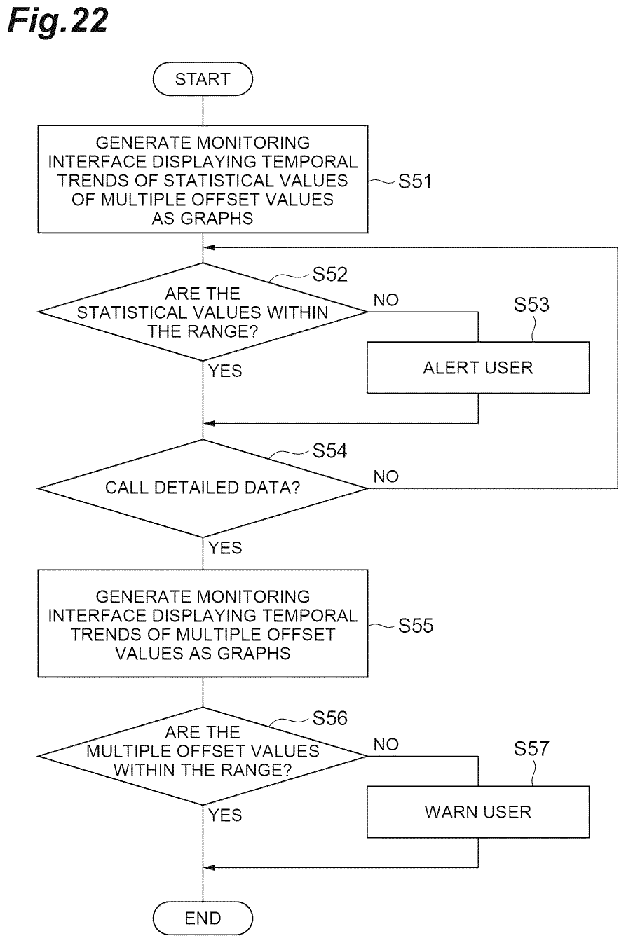

Next, an example of a method for monitoring a plurality of offset values is described. As shown in FIG. 22, this method may be executed in operations S51 to S57 in that order. This method can be carried out by, for each of a plurality of points in time, the offset storage unit 132 storing the plurality of offset values. First, in operation S51, the monitoring unit 142 generates a monitoring interface representing the temporal transitions of the statistical values of the plurality of offset values. For example, as shown in FIG. 21, the offset changing unit 137 may display on the display unit the offset table list 810 including the monitoring interface 93. Then, in operation S52, the monitoring unit 142 determines whether the statistical value of the plurality of offset values is within a threshold range. In the example of FIG. 20, the monitoring unit 142 sets the threshold Th3 in sub-graph 942. In that case, the monitoring unit 142 checks if the range of the plurality of offset values in sub-graph 942 at each of the plurality of points in time is within Th3. If the statistical value is not within the threshold range (operation S52: NO), the monitoring unit 142 may alert the user to an abnormal condition (operation S53). In response to receiving the alert, the user may check the detailed data.

If the statistical value is within the threshold range (operation S52: YES) or after the user is alerted in operation S53, the monitoring unit 142 checks in operation S54 whether the user has called up the detailed data. If the detailed data is not called up (operation S54: NO), the monitoring unit 142 again checks in operation S52 whether the statistical value of the plurality of offset values is within the threshold range. On the other hand, if the detailed data is called up (operation S54: YES), then in operation S55, the monitoring unit 142 generates a monitoring interface 90 that displays graphs of the temporal transitions of the plurality of offset values. For instance, as shown in FIG. 19, the monitoring unit 142 may display on the display unit the graph 91 including sub-graphs 911, 912, and 913, each of which shows the plurality of offset values individually for each of multiple points in time. Along with this, the monitoring unit 142 may also display on the same monitoring interface 90 the graph 92 including sub-graphs 921, 922, and 923, each of which shows the plurality of offset values individually for each of multiple points in time, in the display unit.

Next, in operation S56, the monitoring unit 142 determines whether the plurality of offset values is within the threshold range. For example, in FIG. 19, the monitoring unit 142 sets the threshold Th1 in graph 91. In that case, it is checked whether the plurality of offset values in each of sub-graphs 911, 912, and 913 are within Th1. If the plurality of offset values is not within the threshold range (operation S56: NO), the monitoring unit 142 may alert the user (operation S57). In response to receiving that alert, the user may identify the module and the point in time where and when the abnormal condition occurred, and proceed to investigate the cause or repair that module. If the plurality of offset values is within the threshold range (operation S56: YES) or after an alert to the user, the series of monitoring processes ends.

According to the above recipe setting apparatus, recipe setting method, and recipe setting program, the reference recipe RP1 may include items requiring module-by-module adjustments, and those items can be gathered as a plurality of offset values respectively corresponding to the plurality of modules 111 to 124 in the offset table OT1. The offset table OT1 is stored in association with the reference recipe RP1, and for each module, offset value extraction and the generation of a process recipe based on the extracted offset value and the reference recipe RP1 are performed. Through simple collective editing of the offset table OT1, rather than opening each recipe and searching for the relevant items, the process recipe for each module may substantially be managed. Therefore, the burden of managing recipes in a system where a plurality of modules 111 to 124 is used selectively is reduced.

The recipe setting apparatus 130 may further include the offset editing unit 136 configured to change two or more offset values in the offset table OT1 by the same change amount. In that case, when two or more offset values can be made common, they can be changed in unison, thus further reducing the management burden.

The offset editing unit 136 may be configured to change two or more offset values belonging to the same group by the same change amount, based on a constraint condition defined in advance so as to group the plurality of offset values in the offset table OT1 into one or more groups. In that case, because offset values in the same group can be changed collectively according to the constraint condition, the burden of recipe management is further reduced.

The recipe setting apparatus 130 may further include the condition storage unit 138 storing multiple different default constraint conditions. The offset editing unit 136 may be configured to select a constraint condition from among the plurality of default constraint conditions, and based on the selected constraint condition, changes two or more offset values belonging to the same group by the same change amount. In that case, by switching the constraint condition, the freedom of individually changing each offset value and the convenience of collectively changing two or more offset values may be balanced. Moreover, by enabling constraint condition to be changed through selection from the plurality of default constraint conditions, the workload of changing the constraint conditions themselves is also reduced.

The plurality of default constraint conditions may include: the first condition C1 that places each of the plurality of modules 111 to 124 in an individual group; the second condition C2 that places, among the plurality of modules 111 to 124, two or more modules which are connected to a common source of a processing medium 62A to 62D, in the same group; the third condition C3 that places, among the plurality of modules 111 to 124, two or more modules that are included in one block, in the same group; and the fourth condition C4 that places all modules 111 to 124 in the same group. In that case, the first condition C1 is suitable for a situation where multiple offset values should be adjusted individually (for example, the difference in processing results among modules is large). The second condition C2 is suitable for a situation where two or more modules connected to the common source require adjustment (for instance, if the type of processing medium changes, and the control parameters related to that change must be updated). The third condition C3 is suitable for a situation where multiple offset values should be adjusted collectively (for example, when the difference in processing results occurs among different blocks). The fourth condition C4 is suitable for a situation where all offset values should be adjusted collectively (for example, after the difference in processing results among modules is nearly resolved, aligning each module's results to a common target). Thus, the multiple default constraint conditions can be adapted to various situations.

The offset editing unit 136 may include the offset changing unit 137 configured to cause each of the plurality of modules 111 to 124 to execute processing according to the process recipe, and based on the plurality of results and the constraint condition, changes the offset table OT1. In that case, using the constraint condition and the offset table OT1, adjusting the offset table OT1 may readily be automated.

The offset changing unit 137 may be configured to repeat causing each of the plurality of modules 111 to 124 to execute processing while changing the constraint condition so as to reduce the number of groups, and updating the offset table OT1. In that case, by sequentially changing the constraint condition so as to reduce the number of groups reducing each module's individual variation and adjusting the average result of the plurality of modules 111 to 124 are executed in a stepwise manner.

The offset changing unit 137 modifies, under the constraint condition that places each of the plurality of modules 111 to 124 in an individual group (the first condition C1), the offset table OT1 so as to reduce the difference among the plurality of processing results, and modifies, under the constraint condition that places all of the modules 111 to 124 in the same group, the offset table OT1 so as to bring the average of the plurality of processing results closer to the target. By clearly separating a stage for reducing individual variation among the plurality of modules 111 to 124 from a stage for adjusting average processing results of the plurality of modules 111 to 124, the offset table OT1 can be adjusted more efficiently.

The offset editing unit 136 may include the manual changing unit 139 configured to change the offset table OT1 based on user input. In that case, by making the offset table OT1 a subject of user editing, the user's burden in managing recipes is reduced.

The manual changing unit 139 may be configured to generate an input interface 82 that lists the plurality of offset values in association with the respective modules 111 to 124, and changes the offset table OT1 according to changes in those offset values on the input interface 82. By providing a list display, editing each module's offset value becomes easier.

The recipe setting apparatus 130 may further include the history display unit 140 configured to display on the input interface 82 the change history 86 of the offset table OT1 made by the manual changing unit 139. Enabling the user to check the change history 86 prevents redundant review processes and further reduces the user's burden in recipe management.

The recipe setting apparatus 130 may further include the rollback unit 141 configured to restore the offset table OT1 to a past state selected in the change history 86. In that case, the offset table OT1 may readily be reverted to a previous state.

The manual changing unit 139 may be configured to further generate a second input interface 87 that displays a recipe list 89 in association with the offset table OT1, the recipe list 89 including the reference recipe RP1, and associates another reference recipe with the offset table OT1 in response to an addition of that other reference recipe to the recipe list 89 on the second input interface 87. The offset table OT1 that had been associated with the reference recipe RP1 can readily be applied to another reference recipe as well. This can reduce the burden of separately adjusting an offset table for the other reference recipe.

The manual changing unit 139 may be configured to: generate, in response to the offset table OT1 being selected, a candidate list 88 that includes one or more reference recipes that can be added to the recipe list 89; and add the one reference recipe selected from the candidate list 88 to the recipe list 89, as the other reference recipe. The other reference recipe can readily be added to the recipe list 89.

The manual changing unit 139 may be configured to generate the candidate list 88 including one or more reference recipes that share, with the reference recipe RP1, an item value corresponding to the plurality of offset values. One or more reference recipes to which the offset table can likely be applied are included in the candidate list 88, the other reference recipe can readily be added to the recipe list.

Each of the plurality of modules 111 to 124 may include a rotational holding unit 50 configured to hold and rotate the wafer W and a nozzle 61 configured to discharge the processing liquid onto the wafer W held by the rotational holding unit 50. In that case, the management burden for recipes in liquid processing, where the recipe is precisely adjusted, can be reduced.

The reference recipe RP1 may include a first setting value indicating the rotational speed of wafer W while the processing liquid is being discharged from the nozzle 61 and a second setting value indicating the rotational speed of wafer W after discharge of the processing liquid from nozzle 61 is stopped. The offset table OT1, for each of the plurality of modules 111 to 124, may include an offset value for the first setting value and an offset value for the second setting value. In that case, by gathering in the offset table OT1 the offset values for the first setting value and the second setting value, which both are suitable for individual adjustment of film thickness, the process recipe can be more readily adjusted based on film thickness.

Each module among the plurality of modules 111 to 124 may be connected to one or more sources 62 of the processing liquid, and the recipe storage unit 131 may further store the source recipe RP2 including: a third setting value indicating the timing for stopping supply of the processing liquid from one or more of the sources 62, and a fourth setting value indicating the discharge pressure of the processing liquid from one or more of the sources 62. Because the supply timing and the discharge pressure of the processing liquid are parameters that affect the film thickness, adjusting them allows even more precise tuning of the film thickness. Furthermore, by storing the source recipe RP2 separately from the reference recipe RP1 and the offset table OT1, each recipe may be managed with greater flexibility. For example, the recipe may be adjusted source-by-source, separately from the module-by-module adjustments.

The recipe setting apparatus 130 may include a plurality of sources 62A to 62D as the one or more sources 62, and the recipe storage unit 131 stores the source recipe RP2 corresponding to each of these plurality of sources 62A to 62D. In that case, by storing, for each source 62, the source recipe RP2 without dividing it into control parameters and offset values, the operating conditions for source 62 during standalone operational checks can be matched to those used when actually processing the wafer W, thus improving the reliability of the source's standalone operational checks.

The offset storage unit 132 may store the plurality of offset values at each of multiple points in time, and the recipe setting apparatus 130 may further include the monitoring unit 142 configured to generate a monitoring interface 90 displaying the temporal transitions of the plurality of offset values based on the values stored at each of those points. In that case, even in a situation where changes to offset values have not yet clearly appeared in the processing results, any abnormalities in the substrate processing apparatus may early be detected by monitoring the changes in the offset values over time.

The monitoring unit 142 may be configured to generate a monitoring interface90 that displays, graphs 91 and 92 displaying the temporal transitions of the plurality of offset values. In that case, the visibility of changes in the plurality of offset values over time can be improved.

The monitoring unit 142 may be configured to generate the monitoring interface 90 that displays a graph 91 containing sub-graphs 911 to 913 for showing each offset value individually for each of multiple points in time, and a graph 92 containing sub-graphs 921 to 923 for showing each offset value individually for each of multiple points in time. In that case, both the changes of the plurality of offset values over time and the variation among those offset values can be made easier to see.

The monitoring unit 142 may be configured to generate a monitoring interface 93 representing the temporal transitions of the statistical values of the plurality of offset values. In that case, the overall trends of changes in the plurality of offset values are easier to capture.

The statistical values may include an average or a median of the plurality of offset values and a dispersion measure of the plurality of offset values. The monitoring unit 142 generates a monitoring interface 93 representing the temporal transitions of both the average or the median and the dispersion. In that case, both the temporal changes in the plurality of offset values themselves and the temporal changes in the variation among them can readily be understood.

Each of the plurality of modules 111 to 124 may include a rotational holding unit 50 configured to hold and rotate the wafer W, and a nozzle 61 configured to discharge the processing liquid onto the wafer W held by the rotational holding unit 50. The reference recipe RP1 may include a first setting value indicating the rotational speed of wafer W while the processing liquid is being discharged from the nozzle 61, and a second setting value indicating the rotational speed of wafer W after the discharge of the processing liquid from the nozzle 61 is stopped. The offset table OT1 may include, for each of the plurality of modules 111 to 124, an offset value for the first setting value and an offset value for the second setting value. The monitoring unit 142 may be configured to display in the monitoring interface 90 both the temporal transition of the plurality of offset values for the first setting value and the temporal transition of the plurality of offset values for the second setting value. In that case, by adjusting the offset values for the first setting value and for the second setting value, the film thickness can be controlled. Since the monitoring unit 142 displays both the offset values for the first setting value and for the second setting value in one place, users can immediately see the history of film thickness adjustments.

The main points of this disclosure are described below as [E1] to [E28].
[E1] A recipe setting apparatus comprising:
a recipe storage storing a reference recipe indicating conditions for a process on a substrate;
an offset storage storing, in association with the reference recipe, an offset table including a plurality of offset values respectively corresponding to a plurality of processing devices; and
circuitry configured to:
   select one device from the plurality of processing devices;
   extract an offset value corresponding to the selected device from the plurality of offset values; and
   generate a process recipe, to cause the selected device to execute the process on the substrate according to the process recipe, based on the reference recipe and the extracted offset value.
[E2] The recipe setting apparatus according to [E1], wherein the circuitry is further configured to change two or more offset values in the offset table by an identical change amount.
[E3] The recipe setting apparatus according to [E2], wherein the circuitry is configured to change the two or more offset values by the same change amount, based on a predetermined constraint condition that groups the two or more devices of the plurality of processing devices together, the two or more devices corresponding to the two or more offset values.
[E4] The recipe setting apparatus according to [E3], further comprising a condition storage storing a plurality of different default constraint conditions,
wherein circuitry is configured to:
   select the constraint condition from the plurality of default constraint conditions; and
   change the two or more offset values by the same change amount based on the selected constraint condition.
[E5] The recipe setting apparatus according to [E4], wherein the plurality of default constraint conditions include:
a first condition that groups the plurality of processing devices into separate groups;
a second condition that groups, as the two or more devices, common source devices of the plurality of processing devices together, the common source devices connected to a common source of a processing medium that is provided on the substrate for the processing;
a third condition that groups, as the two or more devices, common block devices of the plurality of processing devices together, the common group devices are included in one block in a substrate processing system together; and
a fourth condition that groups, as the two or more devices, all of the plurality of processing devices together.
[E6] The recipe setting apparatus according to any one of [E3] to [E5], wherein the circuitry is configured to:
cause each of the plurality of processing devices to execute the processing according to the process recipe; and
change the offset table based on a plurality of processing results obtained by the plurality of processing devices and the constraint condition.
[E7] The recipe setting apparatus according to [E6], wherein the circuitry is configured to repeat operations including:
cause each of the plurality of processing devices to execute the processing;
change the offset table based on a plurality of processing results obtained by the plurality of processing devices and the constraint condition;
change the constraint condition so as to reduce number of groups of the plurality of processing devices.
[E8] The recipe setting apparatus according to [E6] or [E7], wherein the circuitry is configured to:
change the offset table under the constraint condition that groups the plurality of processing devices into separate groups so as to reduce differences among the plurality of processing results; and
change the offset table under the constraint condition that groups all of the plurality of processing devices together so as to bring an average of the plurality of processing results closer to a target.
[E9] The recipe setting apparatus according any one of [E2] to [E8], wherein circuitry is configured to change the offset table based on a user input.
[E10] The recipe setting apparatus according to [E9], wherein the circuitry is configured to:
generate an input interface that displays the plurality of offset values in a list, each in association with a respective device of the plurality of processing devices; and
change the offset table in accordance with a change made to the plurality of offset values in the input interface.
[E11] The recipe setting apparatus according to [E10], wherein the circuitry is further configured to display, on the input interface, a history of changes made to the offset table.
[E12] The recipe setting apparatus according to [E11], wherein the circuitry is further configured to revert the offset table to a past state selected from the change history.
[E13] The recipe setting apparatus according to any one of [E9] to [E12], wherein the circuitry is configured to:
further generate a second input interface that displays a recipe list in association with the offset table, the recipe list including the reference recipe; and
associate another reference recipe with the offset table in accordance with addition of the other reference recipe to the recipe list on the second input interface.
[E14] The recipe setting apparatus according to [E13], wherein the circuitry is configured to:
generate a candidate list including one or more reference recipes that can be added to the recipe list in response to the offset table being selected; and
add one reference recipe selected from the candidate list to the recipe list as the other reference recipe.
[E15] The recipe setting apparatus according to [E14], wherein the reference recipe includes a reference item to be modified by one of the plurality of offset values,
wherein the circuitry is configured to generate the candidate list including one or more reference recipes each of which has a reference item to be modified by one of the plurality of offset values, the reference item of the reference recipe and the reference item of each of the one or more reference recipes being having identical values.
[E16] The recipe setting apparatus according to any one of [E1] to [E15], wherein each of the plurality of processing devices includes:
a rotational holder configured to hold and rotate the substrate; and
a processing liquid nozzle configured to discharge a processing liquid onto the substrate held by the rotational holder.
[E17] The recipe setting apparatus according to [E16], wherein the reference recipe includes:
a first item indicating a rotational speed of the substrate during discharge of the processing liquid from the processing liquid nozzle; and
a second item indicating a rotational speed of the substrate after the discharge of the processing liquid from the processing liquid nozzle is stopped, and
wherein the offset table, for each of the plurality of processing devices, includes a first offset value for the first item and a second offset value for the second item.
[E18] The recipe setting apparatus according to [E17], wherein each of the plurality of processing devices is connected to one or more sources of the processing liquid, and
wherein the recipe storage is further configured stores a source recipe including:
   a third item indicating a timing at which supply of the processing liquid from one or more of the sources is stopped; and
   a fourth item indicating a discharge pressure of the processing liquid from one or more of the sources.
[E19] The recipe setting apparatus according to [E18], each of the plurality of processing devices wherein the one or more sources of a plurality of sources, and
wherein the recipe storage unit is configured to store the source recipe corresponding to each of the plurality of sources.
[E20] The recipe setting apparatus according to any one of [E1] to [E18], wherein the offset storage stores the plurality of offset values for each of a plurality of points in time, and
wherein the circuitry is further configured to generate a monitoring interface that displays a temporal transition of the plurality of offset values based on the plurality of offset values at each of the plurality of points in time.
[E21] The recipe setting apparatus according to [E20], wherein the circuitry is configured to generate the monitoring interface that displays a graph representing the temporal transition of the plurality of offset values.
[E22] The recipe setting apparatus according to [E21], wherein the circuitry is configured to display, on the monitoring interface, the graph that includes a sub-graph showing each of the plurality of offset values at each of the plurality of points in time.
[E23] The recipe setting apparatus according to any one of [E20] to [E22], wherein the circuitry is configured to generate the monitoring interface representing a temporal transition of a statistical value of the plurality of offset values.
[E24] The recipe setting apparatus according to [E23], wherein the statistical value includes an average value of the plurality of offset values and a dispersion value of the plurality of offset values, and
wherein the monitoring unit is configured to generate the monitoring interface that represents temporal transition of each of the average value and the dispersion value.
[E25] The recipe setting apparatus according to any one of [E20] to [E24], wherein each of the plurality of processing devices includes:
   a rotational holder configured to hold and rotate the substrate; and
   a processing liquid nozzle configured to discharge a processing liquid onto the substrate held by the rotational holder,
wherein the reference recipe includes:
   a first item indicating a rotational speed of the substrate during discharge of the processing liquid from the processing liquid nozzle; and
   a second item indicating a rotational speed of the substrate after the discharge of the processing liquid from the processing liquid nozzle is stopped,
wherein the offset table, for each of the plurality of modules, includes a first offset value for the first item and a second offset value for the second item, and
wherein the circuitry is configured to display, on the monitoring interface, both the temporal transition of the plurality of offset values for the first setting value and the temporal transition of the plurality of offset values for the second setting value.
[E26] A recipe setting method comprising:
storing a reference recipe indicating conditions for substrate processing;
storing, in association with the reference recipe, an offset table that includes a plurality of offset values respectively corresponding to a plurality of modules of a substrate processing apparatus;
selecting one module from the plurality of modules;
extracting, from the plurality of offset values, an offset value corresponding to the selected module; and
generating a process recipe, to be executed by the selected module, based on the reference recipe and the extracted offset value.
[E27] A program for causing a computer to execute a recipe setting method, the method comprising:
storing a reference recipe indicating conditions for substrate processing;
storing, in association with the reference recipe, an offset table that includes a plurality of offset values respectively corresponding to a plurality of modules of a substrate processing apparatus;
selecting one module from the plurality of modules;
extracting, from the plurality of offset values, an offset value corresponding to the selected module; and
generating a process recipe, to be executed by the selected module, based on the reference recipe and the extracted offset value.
[E28] A computer-readable storage medium storing the program according to [E27].

It is to be understood that not all aspects, advantages and features described herein may necessarily be achieved by, or included in, any one particular example. Indeed, having described and illustrated various examples herein, it should be apparent that other examples may be modified in arrangement and detail.

What is claimed is:

1. A substrate processing apparatus comprising:
a plurality of processing devices each configured to execute a process on a substrate; a recipe storage storing a reference recipe indicating conditions for the process;
an offset storage storing, in association with the reference recipe, an offset table including a plurality of offset values respectively corresponding to a plurality of processing devices; and
circuitry configured to:
select one device from the plurality of processing devices;
extract an offset value corresponding to the selected device from the plurality of offset values; and
generate a process recipe, based on the reference recipe and the extracted offset value; and
cause the selected device to execute the process on the substrate according to the generated process recipe.

2. The substrate processing apparatus according to claim 1, wherein each of the plurality of processing devices includes:
a rotational holder configured to hold and rotate the substrate; and
a processing liquid nozzle configured to discharge a processing liquid onto the substrate held by the rotational holder.

3. The substrate processing apparatus according to claim 2, wherein the reference recipe includes:
a first item indicating a rotational speed of the substrate during discharge of the processing liquid from the processing liquid nozzle; and
a second item indicating a rotational speed of the substrate after the discharge of the processing liquid from the processing liquid nozzle is stopped, and
wherein the offset table, for each of the plurality of processing devices, includes a first offset value for the first item and a second offset value for the second item.

4. The substrate processing apparatus according to claim 3, wherein each of the plurality of processing devices is connected to one or more sources of the processing liquid, and
wherein the recipe storage is further configured stores a source recipe including:
a third item indicating a timing at which supply of the processing liquid from one or more of the sources is stopped; and
a fourth item indicating a discharge pressure of the processing liquid from one or more of the sources.

5. The substrate processing apparatus according to claim 4, wherein the one or more sources include a plurality of sources, and
wherein the recipe storage is configured to store the source recipe corresponding to each of the plurality of sources.

6. The substrate processing apparatus according to claim 1, wherein the circuitry is further configured to change two or more offset values in the offset table by an identical change amount.

7. The substrate processing apparatus according to claim 6, wherein the circuitry is configured to change the two or more offset values by the identical change amount, based on a predetermined constraint condition that groups the two or more devices of the plurality of processing devices together, the two or more devices corresponding to the two or more offset values.

8. The substrate processing apparatus according to claim 7, further comprising a condition storage storing a plurality of different default constraint conditions,
wherein circuitry is configured to:
select the constraint condition from the plurality of default constraint conditions; and
change the two or more offset values by the identical change amount based on the selected constraint condition.

9. The substrate processing apparatus according to claim 8, wherein the plurality of default constraint conditions include:
a first condition that groups the plurality of processing devices into separate groups;
a second condition that groups, as the two or more devices, common source devices of the plurality of processing devices together, the common source devices connected to a common source of a processing medium that is provided on the substrate for the processing;
a third condition that groups, as the two or more devices, common block devices of the plurality of processing devices together, the common block devices are included in one block in the substrate processing system together; and
a fourth condition that groups, as the two or more devices, all of the plurality of processing devices together.

10. The substrate processing apparatus according to claim 7, wherein the circuitry is configured to:
change the offset table based on a plurality of processing results obtained by the plurality of processing devices and the constraint condition.

11. The substrate processing apparatus according to claim 10, wherein the circuitry is configured to repeat operations including:
cause each of the plurality of processing devices to execute the processing;
change the offset table based on a plurality of processing results obtained by the plurality of processing devices and the constraint condition;
change the constraint condition so as to reduce number of groups of the plurality of processing devices.

12. The substrate processing apparatus according to claim 10, wherein the circuitry is configured to:
change the offset table under the constraint condition that groups the plurality of processing devices into separate groups so as to reduce differences among the plurality of processing results; and
change the offset table under the constraint condition that groups all of the plurality of processing devices together so as to bring an average of the plurality of processing results closer to a target.

13. The substrate processing apparatus according to claim 6, wherein circuitry is configured to change the offset table based on a user input.

14. The substrate processing apparatus according to claim 13, wherein the circuitry is configured to:
generate an input interface that displays the plurality of offset values in a list, wherein each of the plurality of offset values is in association with a respective device of the plurality of processing devices; and
change the offset table in accordance with a change made to the plurality of offset values in the input interface.

15. The substrate processing apparatus according to claim 14, wherein the circuitry is further configured to display, on the input interface, a history of changes made to the offset table.

16. The substrate processing apparatus according to claim 15, wherein the circuitry is further configured to revert the offset table to a past state selected from the history of changes.

17. The substrate processing apparatus according to claim 13, wherein the circuitry is configured to:
further generate a second input interface that displays a recipe list in association with the offset table, the recipe list including the reference recipe; and
associate another reference recipe with the offset table in accordance with addition of the other reference recipe to the recipe list on the second input interface.

18. The substrate processing apparatus according to claim 17, wherein the circuitry is configured to:
generate a candidate list including one or more reference recipes that can be added to the recipe list in response to the offset table being selected; and
add one reference recipe selected from the candidate list to the recipe list as the other reference recipe.

19. The substrate processing apparatus according to claim 18, wherein the reference recipe includes a reference item to be modified by one of the plurality of offset values,
wherein the circuitry is configured to generate the candidate list including one or more reference recipes each of which has a reference item to be modified by one of the plurality of offset values, the reference item of the reference recipe and the reference item of each of the one or more reference recipes being having identical values.

20. The substrate processing apparatus according to claim 1, wherein the offset storage stores the plurality of offset values for each of a plurality of points in time, and
wherein the circuitry is further configured to generate a monitoring interface that displays a temporal transition of the plurality of offset values based on the plurality of offset values at each of the plurality of points in time.

21. The substrate processing apparatus according to claim 20, wherein the circuitry is configured to generate the monitoring interface that displays a graph representing the temporal transition of the plurality of offset values.

22. The substrate processing apparatus according to claim 21, wherein the circuitry is configured to display, on the monitoring interface, the graph that includes a sub-graph showing each of the plurality of offset values at each of the plurality of points in time.

23. The substrate processing apparatus according to claim 20, wherein the circuitry is configured to generate the monitoring interface representing a temporal transition of a statistical value of the plurality of offset values.

24. The substrate processing apparatus according to claim 23, wherein the statistical value includes an average value of the plurality of offset values and a dispersion value of the plurality of offset values, and
wherein the circuitry is configured to generate the monitoring interface that represents temporal transition of each of the average value and the dispersion value.

25. The substrate processing apparatus according to claim 20, wherein each of the plurality of processing devices includes:
a rotational holder configured to hold and rotate the substrate; and
a processing liquid nozzle configured to discharge a processing liquid onto the substrate held by the rotational holder,
wherein the reference recipe includes:
a first item indicating a rotational speed of the substrate during discharge of the processing liquid from the processing liquid nozzle; and
a second item indicating a rotational speed of the substrate after the discharge of the processing liquid from the processing liquid nozzle is stopped,
wherein the offset table, for each of the plurality of processing devices, includes a first offset value for the first item and a second offset value for the second item, and
wherein the circuitry is configured to display, on the monitoring interface, both the temporal transition of the plurality of offset values for the first item and the temporal transition of the plurality of offset values for the second item.

26. An apparatus comprising:
a recipe storage storing a reference recipe indicating conditions for a process on a substrate;
an offset storage storing, in association with the reference recipe, an offset table including a plurality of offset values respectively corresponding to a plurality of processing devices; and
circuitry configured to:
select one device from the plurality of processing devices;
extract an offset value corresponding to the selected device from the plurality of offset values; and
generate a process recipe, to cause the selected device to execute the process on the substrate according to the process recipe, based on the reference recipe and the extracted offset value.

27. A method comprising:
storing a reference recipe indicating conditions for a process on a substrate;
storing, in association with the reference recipe, an offset table that includes a plurality of offset values respectively corresponding to a plurality of processing devices of a substrate processing apparatus;
selecting one device from the plurality of processing devices;
extracting, from the plurality of offset values, an offset value corresponding to the selected device;
generating a process recipe based on the reference recipe and the extracted offset value; and
causing the selected device to execute the process on the substrate according to the generated process recipe.

28. A computer-readable storage medium storing a program for causing an apparatus to execute the method according to claim 27.
